(19) United States
(12) Patent Application Publication
(10) Pub. No.: US 2026/0090124 A1
(43) Pub. Date: Mar. 26, 2026

(54) IMAGE SENSOR AND METHOD OF MANFUACTURING THE SAME

(71) Applicant: Taiwan Semiconductor Manufacturing Company, Ltd., Hsinchu (TW)

(72) Inventors: Chih-Kuan Yu, Nantou County (TW); Feng-Chi Hung, Chu-Bei City (TW); Shyh-Fann Ting, Tainan City (TW); Dun-Nian Yaung, Taipei City (TW)

(21) Appl. No.: 19/013,176

(22) Filed: Jan. 8, 2025

Related U.S. Application Data
(60) Provisional application No. 63/698,630, filed on Sep. 25, 2024.

(51) Int. Cl. H10F 39/00; H01L 23/00; H01L 23/522; H01L 25/04

(52) U.S. Cl. CPC H10F 39/809; H10F 39/018; H10F 39/811; H10W 20/496; H10W 90/00; H10W 80/312; H10W 80/327; H10W 90/792

(57) ABSTRACT

An integrated chip includes a photodetector, a transfer transistor, a first pixel transistor, a capacitor, a second pixel transistor, and a bonding structure. A first terminal of the transfer transistor is coupled to a first terminal of the photodetector. The first pixel transistor is on a first semiconductor chip. A first terminal of the first pixel transistor is coupled to a second terminal of the transfer transistor. The capacitor is on the first semiconductor chip. A first terminal of the capacitor is coupled to a second terminal of the first pixel transistor. The second pixel transistor is on a second semiconductor chip bonded to the first semiconductor chip. The bonding structure is at an interface where the first semiconductor chip and the second semiconductor chip are bonded together. The bonding structure couples the second terminal of the capacitor to the first terminal of the second pixel transistor.

### REFERENCE TO RELATED APPLICATION

This Application claims the benefit of U.S. Provisional Application No. 63/698,630, filed on Sep. 25, 2024, the contents of which are hereby incorporated by reference in their entirety.

### BACKGROUND

Complementary metal-oxide semiconductor (CMOS) image sensors are used in a wide range of modern-day electronic devices, such as, for example, cameras, tablets, smart phones, and so on. CMOS image sensors may be front-side illuminated (FSI) or back-side illuminated (BSI). Compared to FSI image sensors, BSI image sensors have better sensitivity, better angular response, and greater metal routing flexibility.

Many modern integrated chips include transistors as well as passive devices. Some examples of passive devices include capacitors, resistors, inductors, varactors, etc. Passive devices are widely used to control integrated chip characteristics, such as gains, time constants, etc. Some passive devices include integrated passive devices (IPDs). An IPD is a collection of one or more passive devices embedded into a single monolithic device and packaged as an integrated circuit (IC).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip comprising a first LOFIC on a first semiconductor chip and a pixel transistor coupled to the first LOFIC and on a second semiconductor chip bonded to the first semiconductor chip.

FIG. 2 illustrates a top view of some embodiments of the integrated chip of FIG. 1.

FIG. 3 illustrates a circuit diagram of some embodiments of the integrated chip of FIG. 1.

FIG. 4 illustrates a circuit diagram of some embodiments of the integrated chip of FIG. 3 in which an application specific integrated circuit (ASIC) is on the second semiconductor chip.

FIG. 5 illustrates a cross-sectional view of some embodiments of the integrated chip of FIG. 4.

FIG. 6 illustrates a circuit diagram of some embodiments of the integrated chip of FIG. 4 further comprising a third semiconductor chip bonded to the first semiconductor chip.

FIG. 7 illustrates a cross-sectional view of some embodiments of the integrated chip of FIG. 6.

FIG. 8 illustrates a cross-sectional view of some other embodiments of the integrated chip of FIG. 6.

FIG. 9 illustrates a circuit diagram of some embodiments of the integrated chip of FIG. 6 in which the pixel transistor is on the third semiconductor chip.

FIG. 10 illustrates a cross-sectional view of some embodiments of the integrated chip of FIG. 9.

FIG. 11 illustrates a circuit diagram of some embodiments of the integrated chip of FIG. 4 in which a second LOFIC is on the first semiconductor chip.

FIG. 12 illustrates a cross-sectional view of some embodiments of the integrated chip of FIG. 11.

FIG. 13 illustrates a circuit diagram of some embodiments of the integrated chip of FIG. 6 in which the second LOFIC is on the first semiconductor chip.

FIG. 14 illustrates a cross-sectional view of some embodiments of the integrated chip of FIG. 13.

FIG. 15 illustrates a cross-sectional view of some other embodiments of the integrated chip of FIG. 13.

FIG. 16 illustrates a circuit diagram of some embodiments of the integrated chip of FIG. 9 in which the second LOFIC is on the first semiconductor chip.

FIG. 17 illustrates a cross-sectional view of some embodiments of the integrated chip of FIG. 16.

FIGS. 18-20 illustrate cross-sectional views of various embodiments of the first LOFIC.

FIGS. 21-24 illustrate cross-sectional views of various embodiments of the first LOFIC and the second LOFIC.

FIGS. 25-29 illustrate cross-sectional views of some embodiments of a method for forming an integrated chip comprising a first LOFIC on a first semiconductor chip and a pixel transistor on a separate chip bonded to the first semiconductor chip.

FIGS. 30-35 illustrate cross-sectional views of some other embodiments of a method for forming an integrated chip comprising a first LOFIC on a first semiconductor chip and a pixel transistor on a separate chip bonded to the first semiconductor chip.

FIGS. 36-40 illustrate cross-sectional views of some other embodiments of a method for forming an integrated chip comprising a first LOFIC on a first semiconductor chip and a pixel transistor on a separate chip bonded to the first semiconductor chip.

FIG. 41 illustrates a flow diagram of some embodiments of a method for forming an integrated chip comprising a first capacitor on a first semiconductor chip and a pixel transistor on a separate chip bonded to the first semiconductor chip.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip includes an image sensor. The image sensor includes a plurality of pixels. A pixel includes a photodetector and a transfer transistor coupled to the photodetector. The pixel includes a first pixel transistor on a first semiconductor chip and coupled to the transfer transistor. The pixel includes a lateral overflow integration capacitor (LOFIC) on the first semiconductor chip. A first electrode of the LOFIC is coupled to the first pixel transistor by first conductive interconnects on the first semiconductor chip. A second electrode of the LOFIC is coupled to a second pixel transistor by second conductive interconnects.

In some cases, the second pixel transistor is on the first semiconductor chip and thus the second conductive interconnects are on the first semiconductor chip. However, when the second pixel transistor and the second conductive interconnects are on the first semiconductor chip, it may be difficult to decrease the pitch of the pixels (e.g., the distance between the centers of neighboring pixels) of the image sensor. For example, the second interconnects may increase the complexity of the interconnect routing on the first semiconductor chip. Thus, the design flexibility of the interconnect routing on the first semiconductor chip may be reduced, which may make reducing the pitch of the pixels more difficult. Further, the second pixel transistor and second conductive interconnects may take up substantial space on the first semiconductor chip, which may make reducing the pitch of the pixels more difficult.

In various embodiments of the present disclosure, the second pixel transistor is on a second semiconductor chip that is bonded to the first semiconductor chip. By moving the second pixel transistor to the second semiconductor chip, at least a portion of the second interconnects can be omitted from the first semiconductor chip. Thus, the difficulty of decreasing the pitch of the pixels can be reduced. For example, the complexity of the interconnect routing on the first semiconductor chip can be reduced, the design flexibility of the interconnect routing on the first semiconductor chip can be improved, and the available space on the first semiconductor chip can be increased. Thus, the difficulty of reducing the pitch of the pixels can be reduced.

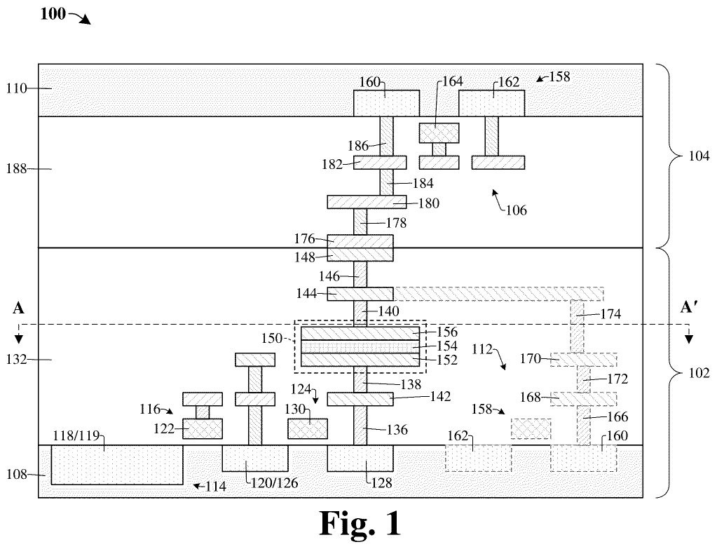

FIG. 1 illustrates a cross-sectional view 100 of some embodiments of an integrated chip comprising a first LOFIC 150 on a first semiconductor chip 102 and a pixel transistor 158 coupled to the first LOFIC 150 and on a second semiconductor chip 104 bonded to the first semiconductor chip 102.

The integrated chip includes a first semiconductor chip 102 and a second semiconductor chip 104 bonded to the first semiconductor chip 102. The first semiconductor chip 102 includes a first semiconductor substrate 108. The second semiconductor chip 104 includes a second semiconductor substrate 110.

The integrated chip includes a plurality of pixels. A pixel includes a photodetector 114 and a transfer transistor 116. The photodetector 114 and the transfer transistor 116 are on the first semiconductor chip 102 and disposed along the first semiconductor substrate 108. In some embodiments, the photodetector 114 is a photodiode formed by the first semiconductor substrate 108 and a photodiode region 118 in the first semiconductor substrate 108 (e.g., a doped region in the first semiconductor substrate 108 having a doping type different than that of the first semiconductor substrate 108). The transfer transistor 116 includes a first source/drain 119 along the first semiconductor substrate 108, a second source/drain 120 along the first semiconductor substrate 108, and a gate 122 along the first semiconductor substrate 108 and between the first source/drain 119 and the second source/drain 120. In some embodiments, the photodiode region 118 forms the first source/drain 119 of the transfer transistor 116 (e.g., photodiode region 118 and source/drain 119 are one and the same).

A first pixel transistor 124 is on the first semiconductor chip 102. The first pixel transistor 124 is disposed along the first semiconductor substrate 108 and includes a first source/drain 126, a second source/drain 128, and a gate 130 between the first source/drain 126 and the second source/drain 128. In some embodiments, source/drain 126 and source/drain 120 are one and the same. In some other embodiments, source/drain 120 is separate from source/drain 126 and the two are coupled by conductive interconnects on the first semiconductor chip 102.

A first dielectric structure 132 comprising a first plurality of dielectric layers (not shown) is on the first semiconductor chip 102. A first interconnect structure comprising a first plurality of conductive interconnects (e.g., conductive contact 136, conductive vias 138, 140, conductive lines 142, 144, conductive bonding contact 146, conductive bonding pad 148) is on the first semiconductor chip 102 and within the first dielectric structure 132.

A first lateral overflow integration capacitor (LOFIC) 150 is on the first semiconductor chip 102. The first LOFIC 150 includes a first electrode layer 152, a second electrode layer 156, and a dielectric layer 154 between the first electrode layer 152 and the second electrode layer 156. The first electrode layer 152 of the first LOFIC 150 is coupled to source/drain 128 of the first pixel transistor 124 by one or more conductive interconnects (e.g., contact 136, conductive line 142, and conductive via 138) on the first semiconductor chip 102. A conductive via 140 is on and coupled to the second electrode layer 156. A conductive line 144 is on and coupled to conductive via 140.

A first source/drain 160 of a second pixel transistor 158 is coupled to the second electrode 156 of the first LOFIC 150 through conductive line 144 and conductive via 140. In some integrated chips, the second pixel transistor 158 is on the same chip as the first LOFIC 150 (e.g., the second pixel transistor 158 is on the first semiconductor chip 102), as illustrated at 112. In such chips, additional interconnects are disposed on the first semiconductor chip 102 to couple the first source/drain 160 of the second pixel transistor 158 to conductive line 144 and thus to the second electrode 156 of the first LOFIC 150. For example, an additional contact 166, additional conductive lines 168, 170, and additional conductive vias 172, 174 are on the first semiconductor chip 102 and couple the first source/drain 160 of the second pixel transistor 158 to conductive line 144. However, these additional interconnects may increase the complexity of the interconnect routing on the first semiconductor chip 102 and reduce the available space for the interconnect routing on the first semiconductor chip 102. As a result, the difficulty of decreasing the pitch of the pixels on the integrated chip may be increased.

In various embodiments of the present disclosure, the second pixel transistor 158 is on the second semiconductor chip 104, as illustrated at 106. Thus, the additional interconnects (e.g., contact 166, conductive lines 168, 170, and conductive vias 172, 174) can be omitted from the first semiconductor chip 102. As a result, the complexity of the interconnect routing on the first semiconductor chip 102 can be reduced, the design flexibility of the interconnect routing on the first semiconductor chip 102 can be improved, and the available space for the interconnect routing on the first semiconductor chip 102 can be increased. Thus, the difficulty of decreasing the pitch of the pixels on the integrated chip can be reduced.

The second pixel transistor 158 (on the second semiconductor chip 104) is coupled to the second electrode layer 156 of the first LOFIC 150 (on the first semiconductor chip 102) by conductive line 144, conductive via 140, by a bonding structure at an interface between the first semiconductor chip 102 and the second semiconductor chip 104, and by conductive interconnects of a second interconnect structure that is on the second semiconductor chip 104 and within a second dielectric structure 188 of the second semiconductor chip 104. For example, the bonding structure includes a first bonding contact 146 and a first bonding pad 148 on the first semiconductor chip 102. The bonding structure further includes a second bonding contact 178 and a second bonding pad 176 on the second semiconductor chip 104. The first bonding pad 148 is coupled to conductive line 144 (which is coupled the second electrode layer 156 by conductive via 140) by the first bonding contact 146. The second bonding pad 176 is bonded and coupled to the first bonding pad 148. Conductive lines 180, 182 and conductive via(s) 184 on the second semiconductor chip 104 are coupled to the second bonding pad 176 by the second bonding contact 178. The first source/drain 160 of the second pixel transistor 158 is coupled to conductive lines 180, 182 and conductive via 184 by a contact 186 on the second semiconductor chip 104. The second source/drain 162 of the second pixel transistor 158 is coupled to a first reference voltage terminal (e.g., 330 of FIG. 3) by conductive interconnects on the second semiconductor chip 104.

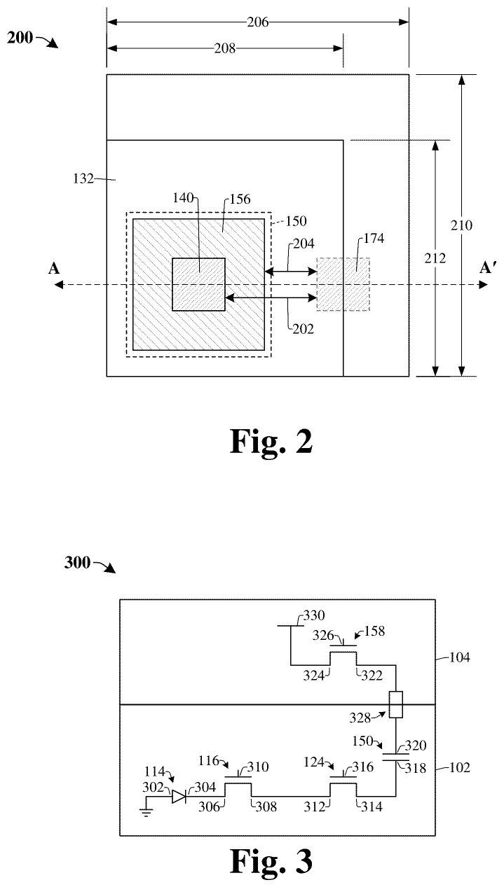

FIG. 2 illustrates a top view 200 of some embodiments of the integrated chip of FIG. 1. In some embodiments, top view 200 is taken across line A-A′ of FIG. 1.

In some embodiments, there is a minimum distance 202 (e.g., a minimum pitch) that must be maintained between conductive via 140 and neighboring conductive vias. Further, in some embodiments, there is a minimum distance 204 that must be maintained between the LOFIC 150 and neighboring conductive vias. Thus, in some integrated chips in which additional conductive via 174 is on the first semiconductor chip 102 (due to the second pixel transistor 158 being on the first semiconductor chip 102), reducing the pixel width and/or the pixel length (e.g., from a first pixel width 206 to a second pixel width 208, and from a first pixel length 210 to a second pixel length 212) while maintaining the minimum distances 202, 204 may be challenging. However, by eliminating additional conductive via 174 from the first semiconductor chip 102 (by disposing the second pixel transistor 158 on the second semiconductor chip 104), the pixel width and/or the pixel length can be more easily reduced. Thus, the pixel pitch can be more easily reduced.

FIG. 3 illustrates a circuit diagram 300 of some embodiments of the integrated chip of FIG. 1.

The photodetector 114 and the transfer transistor 116 are on the first semiconductor chip 102. The photodetector 114 (e.g., a photodiode or the like) has a first terminal 302 (e.g., corresponding to the first semiconductor substrate 108) and a second terminal 304 (e.g., corresponding to the photodiode region 118). In some embodiments, the first terminal 302 is coupled to ground or some other reference voltage source.

The transfer transistor 116 has a first terminal 306 (e.g., corresponding to source/drain 119), a second terminal 308 (e.g., corresponding to source/drain 120), and a control terminal 310 (e.g., corresponding to gate 122). The first terminal 306 is coupled to terminal 304 of the photodetector 114.

The first pixel transistor 124 is on the first semiconductor chip 102. The first pixel transistor 124 has a first terminal 312 (e.g., corresponding to source/drain 126), a second terminal 314 (e.g., corresponding to source/drain 128), and a control terminal 316 (e.g., corresponding to gate 130). The first terminal 312 is coupled to terminal 308 of the transfer transistor 116.

The first LOFIC 150 is on the first semiconductor chip 102. The first LOFIC 150 has a first terminal 318 (e.g., corresponding to the first electrode layer 152) and a second terminal 320 (e.g., corresponding to the second electrode layer 156). The first terminal 318 is coupled to terminal 314 of the first pixel transistor 124.

The second pixel transistor 158 is on the second semiconductor chip 104. The second pixel transistor 158 has a first terminal 322 (e.g., corresponding to source/drain 160), a second terminal 324 (e.g., corresponding to source/drain 162), and a control terminal 326 (e.g., corresponding to gate 164). The first terminal 322 is coupled to terminal 320 of the first LOFIC 150 through a bonding structure 328 (e.g., corresponding to bonding pads 148, 176 and bonding contacts 146, 178). The second terminal 324 is coupled to a first reference voltage terminal 330. In some embodiments, the first reference voltage terminal 330 is coupled to ground. In some other embodiments, the first reference voltage terminal 330 is coupled to a first reference voltage source (not shown).

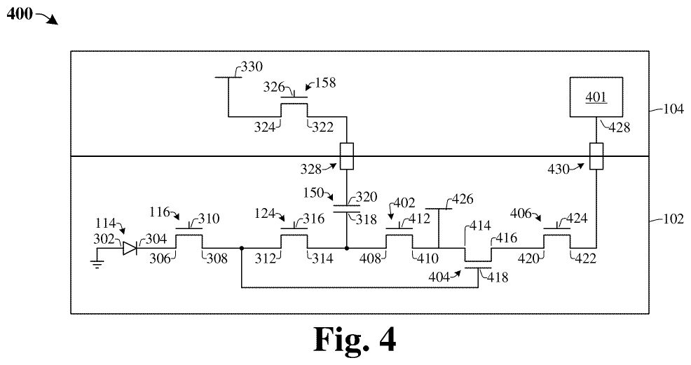

FIG. 4 illustrates a circuit diagram 400 of some embodiments of the integrated chip of FIG. 3 in which an application specific integrated circuit (ASIC) 401 is on the second semiconductor chip 104.

The integrated chip includes a third pixel transistor 402 (e.g., a reset transistor), a fourth pixel transistor 404 (e.g., a source follower transistor), and a fifth pixel transistor 406 (e.g., a row select transistor) on the first semiconductor chip 102.

The third pixel transistor 402 has a first terminal 408, a second terminal 410, and a control terminal 412. Terminal 408 is coupled to terminal 314 of the first pixel transistor 124 and terminal 318 of the first LOFIC 150. Terminal 410 is coupled to a first supply voltage terminal 426. In some embodiments, the first supply voltage terminal 426 is coupled to a first supply voltage source (not shown).

The fourth pixel transistor 404 has a first terminal 414, a second terminal 416, and a control terminal 418. Terminal 414 is coupled to terminal 410 of the third pixel transistor 402 and the first supply voltage terminal 426. Control terminal 418 is coupled to terminal 308 of the transfer transistor 116.

The fifth pixel transistor 406 includes a first terminal 420, a second terminal 422, and a control terminal 424. Terminal 420 is coupled to terminal 416 of the fourth pixel transistor 404. Terminal 422 is coupled to a first terminal 428 of the ASIC 401 through a bonding structure 430 at the interface between the first semiconductor chip 102 and the second semiconductor chip 104.

In some embodiments, the control terminal 310 of the transfer transistor 116, the control terminal 316 of the first pixel transistor 124, the control terminal 326 of the second pixel transistor 158, the control terminal 412 of the third pixel transistor 402, and the control terminal 424 of the fifth pixel transistor 406 are coupled to a control circuit (not shown) of the ASIC 401 and receive control signals from the control circuit.

In some embodiments, the first pixel transistor 124, the third pixel transistor 402, and the first LOFIC 150 may be referred to as a conversion gain circuit. In some embodiments, the first pixel transistor 124 is turned OFF (e.g., by the control circuit of the ASIC 401), the second pixel transistor 158 is turned ON, and the third pixel transistor 402 is turned ON to reset the voltage across the first LOFIC 150 according to the voltage at reference voltage terminal 330 and the voltage at supply voltage terminal 426. In some embodiments, a first conversion gain operation (e.g., a high conversion gain operation) is performed by turning OFF the first pixel transistor 124 to isolate the first LOFIC 150 from terminal 308 of the transfer transistor 116 and control terminal 418 of the fourth pixel transistor 404. In some embodiments, a second conversion gain operation (e.g., a low conversion gain operation) is performed by turning ON the first pixel transistor 124 to couple the first LOFIC 150 to terminal 312 and control terminal 418.

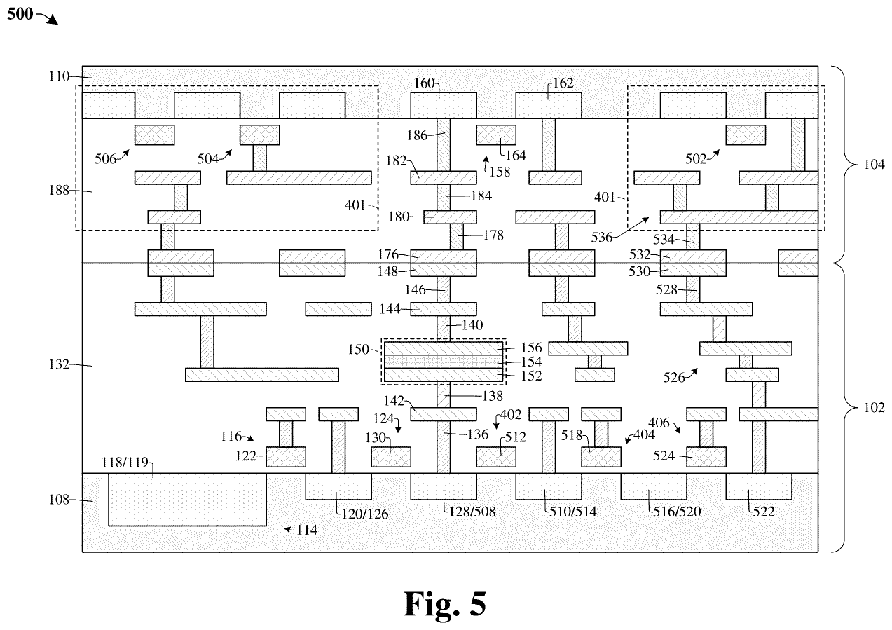

FIG. 5 illustrates a cross-sectional view 500 of some embodiments of the integrated chip of FIG. 4.

In some embodiments, the ASIC 401 includes transistors (e.g., transistors 502, 504, 506) disposed along the second semiconductor substrate 110. The transistors of the ASIC 401 are interconnected by conductive interconnects (not labeled) on the second semiconductor chip 104. The transistors of the ASIC 401 are coupled to conductive interconnects on the first semiconductor chip 102 through conductive interconnects (e.g., contacts, conductive lines, conductive vias, etc.) on the second semiconductor chip 104, bonding pads (e.g., 532) and bonding contacts (e.g., 534) on the second semiconductor chip 104, and bonding pads (e.g., 530) and bonding contacts (e.g., 528) on the first semiconductor chip 102.

The third pixel transistor 402 (e.g., the reset transistor) includes a first source/drain 508 (e.g., corresponding to terminal 408), a second source/drain 510 (e.g., corresponding to terminal 410), and a gate 512 (e.g., corresponding to control terminal 412) between the first source/drain 508 and the second source/drain 510. Source/drain 508 is coupled to source/drain 128. In some embodiments, source/drain 508 and source/drain 128 are one and the same. In some other embodiments, source/drain 508 and source/drain 128 are separate and coupled together by conductive interconnects on the first semiconductor chip 102.

The fourth pixel transistor 404 (e.g., the source follower transistor) includes a first source/drain 514 (e.g., corresponding to terminal 414), a second source/drain 516 (e.g., corresponding to terminal 416), and a gate 518 (e.g., corresponding to control terminal 418) between the first source/drain 514 and the second source/drain 516. Source/drain 514 is coupled to source/drain 510. In some embodiments, source/drain 514 and source/drain 510 are one and the same. In some other embodiments, source/drain 514 and source/drain 510 are separate and coupled together by conductive interconnects on the first semiconductor chip 102. Gate 518 is coupled to source/drain 120 by conductive interconnects (not labeled) on the first semiconductor chip 102. Source/drain 514 is coupled to the first supply voltage terminal (e.g., 426 of FIG. 4) by conductive interconnects.

The fifth pixel transistor 406 (e.g., the row select transistor) includes a first source/drain 520 (e.g., corresponding to terminal 420), a second source/drain 522 (e.g., corresponding to terminal 422), and a gate 524 (e.g., corresponding to control terminal 424) between the first source/drain 520 and the second source/drain 522. Source/drain 520 is coupled to source/drain 516. In some embodiments, source/drain 520 and source/drain 516 are one and the same. In some other embodiments, source/drain 520 and source/drain 516 are separate and coupled together by conductive interconnects on the first semiconductor chip 102. Source/drain 522 is coupled to the ASIC 401 (e.g., source/drain 522 is coupled to a source/drain of transistor 502) through conductive interconnects 526 on the first semiconductor chip 102, a bonding pad 530 and a bonding contact 528 (e.g., corresponding to bonding structure 430) on the first semiconductor chip 102, a bonding pad 532 and a bonding contact 534 (e.g., corresponding to bonding structure 430) on the second semiconductor chip 104, and conductive interconnects 536 on the second semiconductor chip 104.

In some embodiments, the gate 122 of the transfer transistor 116, the gate 130 of the first pixel transistor 124, the gate 164 of the second pixel transistor 158, the gate 512 of the third pixel transistor 402, and the gate 524 of the fifth pixel transistor 406 are coupled to the control circuit (not shown) of the ASIC 401 through conductive interconnects (not shown) on the first semiconductor chip 102 and the second semiconductor chip 104 and through bonding pads (not shown) and bonding contacts (not shown) on the first semiconductor chip 102 and the second semiconductor chip 104.

In some embodiments, source/drains are doped regions of semiconductor substrate. In some other embodiments, source/drains can be epitaxial semiconductor layers or some other suitable source/drain structures. Source/drain region(s) may refer to a source or a drain, individually or collectively dependent upon the context.

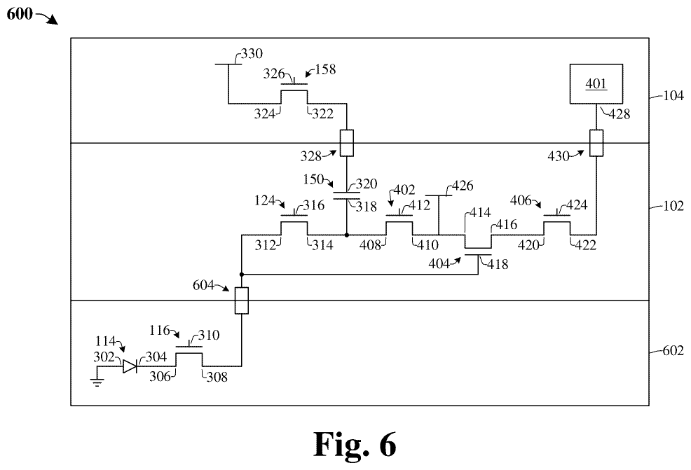

FIG. 6 illustrates a circuit diagram 600 of some embodiments of the integrated chip of FIG. 4 in which the photodetector 114 and the transfer transistor 116 are on a third semiconductor chip 602 bonded to the first semiconductor chip 102.

Terminal 308 of the transfer transistor 116 is coupled to terminal 312 of the first pixel transistor 124 and the control terminal 418 of the fourth pixel transistor 404 through a bonding structure 604 at the interface between the first semiconductor chip 102 and the third semiconductor chip 602.

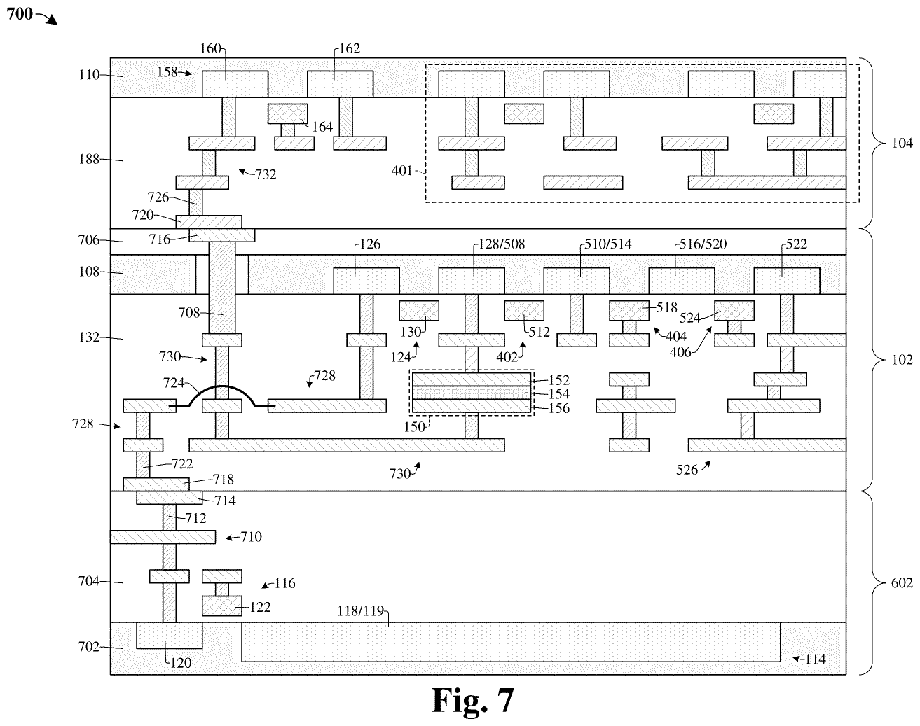

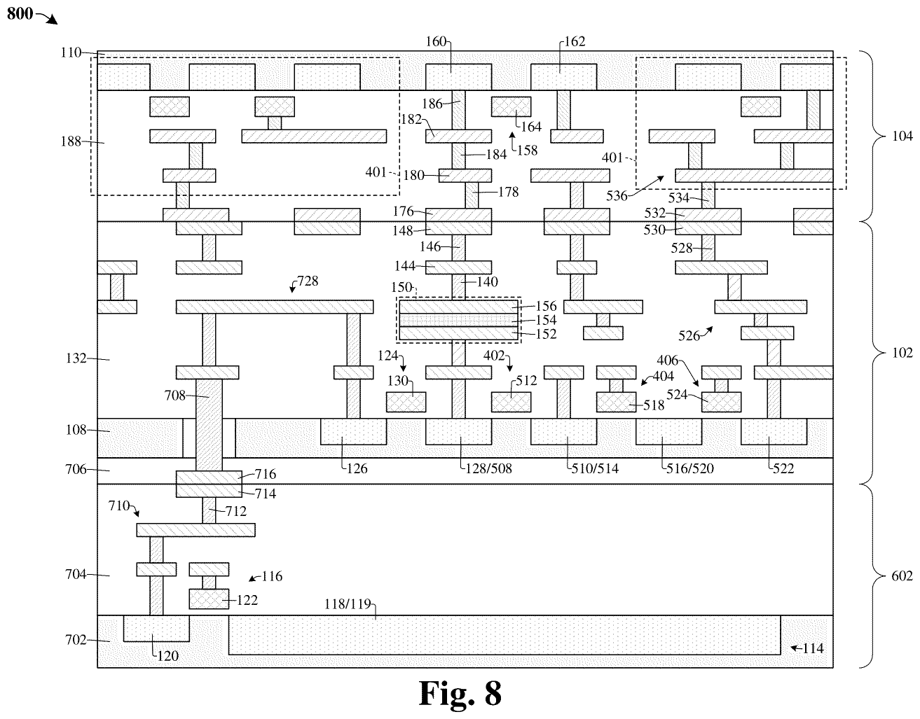

FIG. 7 illustrates a cross-sectional view 700 of some embodiments of the integrated chip of FIG. 6. FIG. 8 illustrates a cross-sectional view 800 of some other embodiments of the integrated chip of FIG. 6.

Referring to FIG. 7 and FIG. 8, third semiconductor chip 602 includes a third semiconductor substrate 702 and a third dielectric structure 704. The photodetector 114 and the transfer transistor 116 are disposed along the third semiconductor substrate 702. For example, photodiode region 118 is in the third semiconductor substrate 702, source/drain 119 is in the third semiconductor substrate 702, source/drain 120 is in the third semiconductor substrate 702, and gate 122 is disposed along the third semiconductor substrate 702 between source/drain 119 and source/drain 120. Conductive interconnects 710, bonding contacts 712, bonding pads 714 are on the third semiconductor chip 602. A backside dielectric layer 706 is on the first semiconductor chip 102 along a backside of the first semiconductor substrate 108. A backside bonding pad 716 is in the backside dielectric layer 706. A through-substrate via (TSV) 708 extends through the first semiconductor substrate 108 from a conductive interconnect in dielectric structure 132 to backside bonding pad 716 in backside dielectric layer 706.

By disposing the photodetector 114 and the transfer transistor 116 on a different chip than pixel transistors 124, 402, 404, 406, the size of the photodetector 114 may be more easily increased and/or the pitch of the pixels may be more easily decreased.

In some embodiments (e.g., as illustrated in FIG. 7), the first semiconductor chip 102 and the third semiconductor chip 602 are bonded in a “face-to-face” configuration and the first semiconductor chip 102 and the second semiconductor chip 104 are bonded in a “back-to-face” configuration. The third semiconductor chip 602 is bonded to the first semiconductor chip 102 along a bonding pad 718 on the first semiconductor chip 102 and a bonding pad 714 on the third semiconductor chip 602. The first semiconductor chip 102 is bonded to the second semiconductor chip 104 along the backside bonding pad 716 of the first semiconductor chip 102 and along a bonding pad 720 of the second semiconductor chip 104. Source/drain 120 is coupled to source/drain 126 through interconnects 710 on the third semiconductor chip 602, bonding pad 714 and bonding contact 712 on the third semiconductor chip 602, bonding pad 718 and bonding contact 722 on the first semiconductor chip 102, and conductive interconnects 728 on the first semiconductor chip 102 (e.g., as illustrated by conductive interconnects 728 and connection 724). The second electrode layer 156 of the first LOFIC 150 is coupled to source/drain 160 of pixel transistor 158 through conductive interconnects 730 on the first semiconductor chip 102, the TSV 708 on the first semiconductor chip 102, bonding pad 716 on the first semiconductor chip 102, bonding pad 720 and bonding contact 726 on the second semiconductor chip 104, and conductive interconnects 732 on the second semiconductor chip 104. Source/drain 522 of pixel transistor 406 is coupled to the ASIC 401 through conductive interconnects 526 on the first semiconductor chip 102, a TSV (not shown) on the first semiconductor chip 102, a backside bonding pad (not shown) on the first semiconductor chip 102, a bonding pad (not shown) and bonding contact (not shown) on the second semiconductor chip 104, and conductive interconnects on the second semiconductor chip 104.

In some other embodiments (e.g., as illustrated in FIG. 8), the first semiconductor chip 102 and the third semiconductor chip 602 are bonded in a “back-to-face” configuration and the first semiconductor chip 102 and the second semiconductor chip 104 are bonded in a “face-to-face” configuration. The third semiconductor chip 602 is bonded to the first semiconductor chip 102 along the backside bonding pad 716 of the first semiconductor chip 102 and bonding pad 714 on the third semiconductor chip 602. The first semiconductor chip 102 is bonded to the second semiconductor chip 104 along bonding pad 148 of the first semiconductor chip 102 and bonding pad 176 of the second semiconductor chip 104. Source/drain 120 is coupled to source/drain 126 through interconnects 710 on the third semiconductor chip 602, bonding pad 714 and bonding contact 712 on the third semiconductor chip 602, bonding pad 716 on the first semiconductor chip 102, TSV 708 on the first semiconductor chip 102, and conductive interconnects 728 on the first semiconductor chip 102.

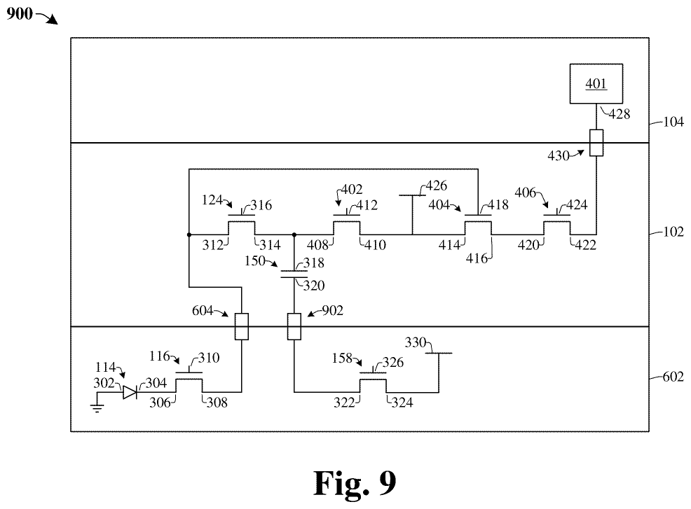

FIG. 9 illustrates a circuit diagram 900 of some embodiments of the integrated chip of FIG. 6 in which the second pixel transistor 158 is on the third semiconductor chip 602.

Terminal 322 of the second pixel transistor 158 is coupled to terminal 320 of the first LOFIC 150 through a bonding structure 902 at the interface between the first semiconductor chip 102 and the third semiconductor chip 602.

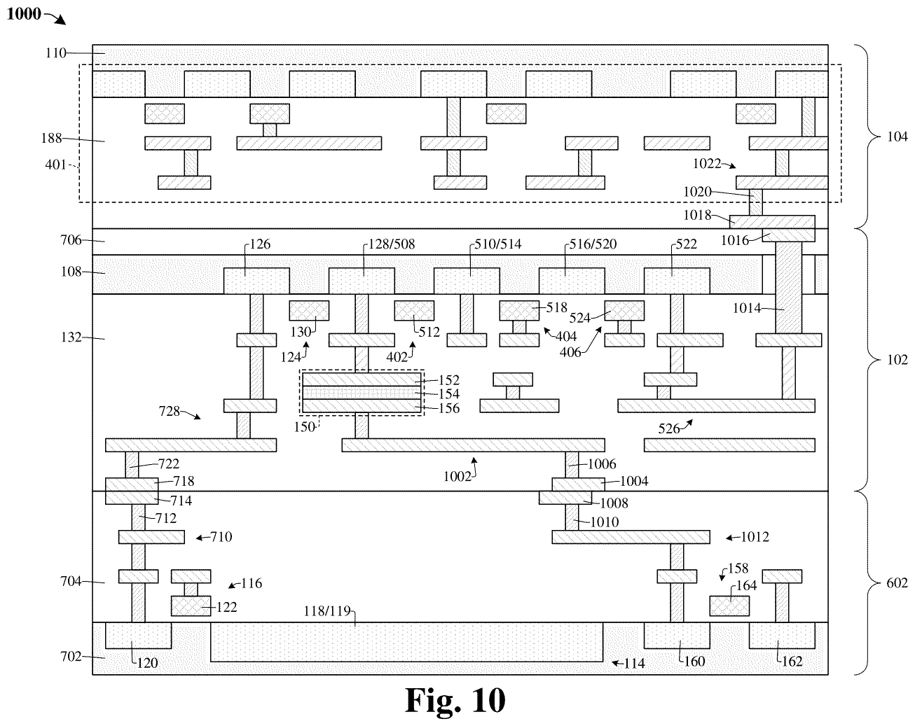

FIG. 10 illustrates a cross-sectional view 1000 of some embodiments of the integrated chip of FIG. 9.

The second pixel transistor 158 is disposed along the semiconductor substrate 702 of the third semiconductor chip 602. The second electrode layer 156 of the first LOFIC 150 is coupled to source/drain 160 of pixel transistor 158 through conductive interconnects 1002 on the first semiconductor chip 102, a bonding pad 1004 and a bonding contact 1006 on the first semiconductor chip 102, a bonding pad 1008 and a bonding contact 1010 on the third semiconductor chip 602, and conductive interconnects 1012 on the third semiconductor chip 602.

Source/drain 522 of pixel transistor 406 is coupled to the ASIC 401 through conductive interconnects 526 on the first semiconductor chip 102, a TSV 1014 on the first semiconductor chip 102, a backside bonding pad 1016 on the first semiconductor chip 102, a bonding pad 1018 and bonding contact 1020 on the second semiconductor chip 104, and conductive interconnects 1022 on the second semiconductor chip 104.

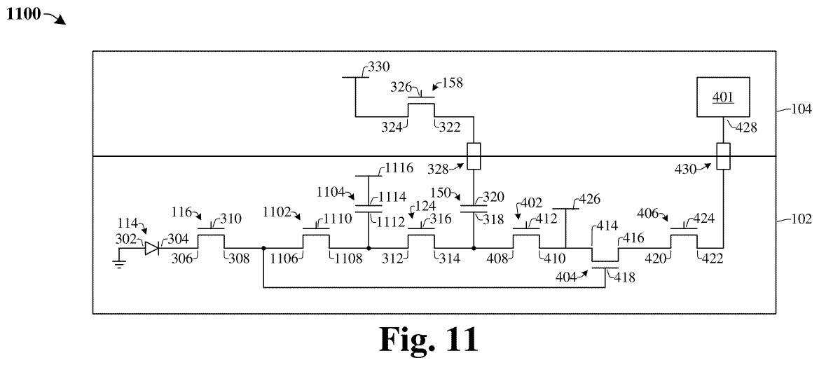

FIG. 11 illustrates a circuit diagram 1100 of some embodiments of the integrated chip of FIG. 4 in which a sixth pixel transistor 1102 and a second LOFIC 1104 are on the first semiconductor chip 102 and coupled between the transfer transistor 116 and the first pixel transistor 124.

The sixth pixel transistor 1102 has a first terminal 1106 coupled to terminal 308 of the transfer transistor 116. The sixth pixel transistor 1102 has a second terminal 1108 coupled to terminal 312 of the first pixel transistor 124. The sixth pixel transistor 1102 has a control terminal 1110. In some embodiments, control terminal 1110 is coupled to the control circuit (not shown) in the ASIC 401 and receives a control signal from the control circuit.

The second LOFIC 1104 has a first terminal 1112 coupled to terminal 1108 of pixel transistor 1102 and terminal 312 of pixel transistor 124. The second LOFIC has a second terminal 1114 coupled to a second reference voltage terminal 1116. In some embodiments, the second reference voltage terminal 1116 is coupled to ground. In some other embodiments, the second reference voltage terminal 1116 is coupled to a reference second voltage source (not shown).

In some embodiments, the first pixel transistor 124, the third pixel transistor 402, the first LOFIC 150, the sixth pixel transistor 1102, and the second LOFIC 1104 may be referred to as a conversion gain circuit. In some embodiments, the sixth pixel transistor 1102 is turned OFF, the first pixel transistor 124 is turned ON, the second pixel transistor 158 is turned ON, and the third pixel transistor 402 is turned ON to reset the voltage across the first LOFIC 150 according to the voltage at reference voltage terminal 330 and the voltage at supply voltage terminal 426 and to reset the voltage across the second LOFIC 1104 according to the voltage at reference voltage terminal 1116 and supply voltage terminal 426. In some embodiments, a first conversion gain operation (e.g., a high conversion gain operation) is performed by turning OFF the sixth pixel transistor 1102 to isolate the first LOFIC 150 and the second LOFIC 1104 from terminal 308 of the transfer transistor 116 and control terminal 418 of the fourth pixel transistor 404. In some embodiments, a second conversion gain operation (e.g., a middle conversion gain operation) is performed by turning ON the sixth pixel transistor 1102 to couple the second LOFIC 1104 to terminal 308 and control terminal 418, and by turning OFF the first pixel transistor 124 to isolate the first LOFIC 150 from terminal 308 and control terminal 418. In some embodiments, a third conversion gain operation (e.g., a low conversion gain operation) is performed by turning ON both the sixth pixel transistor 1102 and the first pixel transistor 124 to couple both the first LOFIC 150 and the second LOFIC to terminal 308 and control terminal 418.

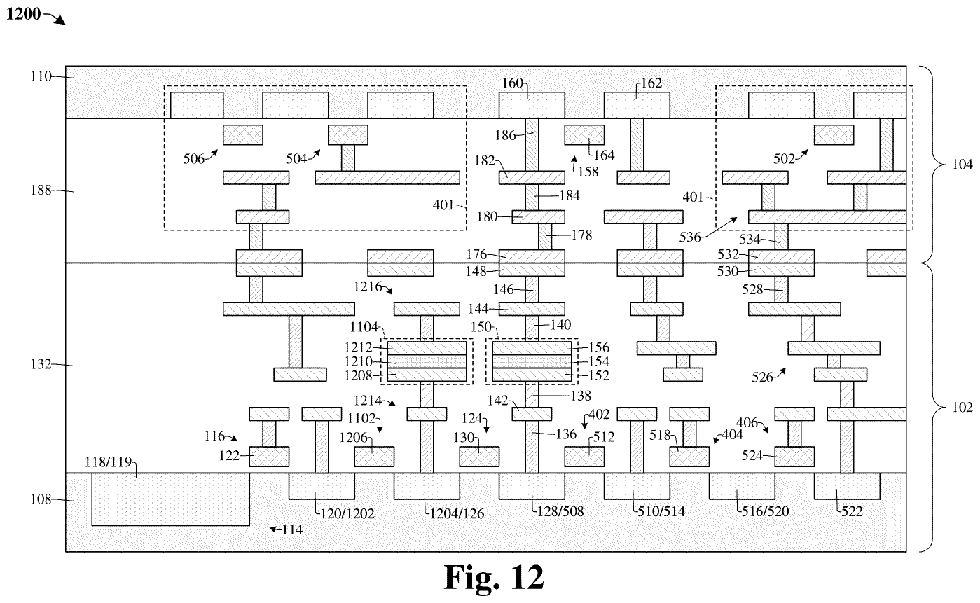

FIG. 12 illustrates a cross-sectional view 1200 of some embodiments of the integrated chip of FIG. 11 (e.g., the integrated chip of FIG. 5 in which the sixth pixel transistor 1102 and the second LOFIC 1104 are on the first semiconductor chip 102 and coupled between the transfer transistor 116 and the first pixel transistor 124).

The sixth pixel transistor 1102 includes a first source/drain 1202 (corresponding to terminal 1106) along the first semiconductor substrate 108, a second source/drain 1204 (e.g., corresponding to terminal 1108) along the first semiconductor substrate 108, and a gate 1206 (e.g., corresponding to control terminal 1110) along the first semiconductor substrate 108 and between source/drain 1202 and source/drain 1204. In some embodiments, source/drain 120 and source/drain 1202 are one and the same. In some other embodiments, source/drain 120 and source/drain 1202 are separate and coupled together by conductive interconnects on the first semiconductor chip 102. In some embodiments, source/drain 1204 and source/drain 126 are one and the same. In some other embodiments, source/drain 1204 and source/drain 126 are separate and coupled together by conductive interconnects on the first semiconductor chip 102.

The second LOFIC 1104 includes a first electrode layer 1208, a second electrode layer 1212, and a dielectric layer 1210 between the first electrode layer 1208 and the second electrode layer 1212. The first electrode layer 1208 is coupled to source/drain 1204 and source/drain 126 by conductive interconnects 1214 on the first semiconductor chip 102. The second electrode layer 1212 is coupled to a reference voltage terminal (e.g., 1116 of FIG. 11) by conductive interconnects 1216 on the first semiconductor chip 102.

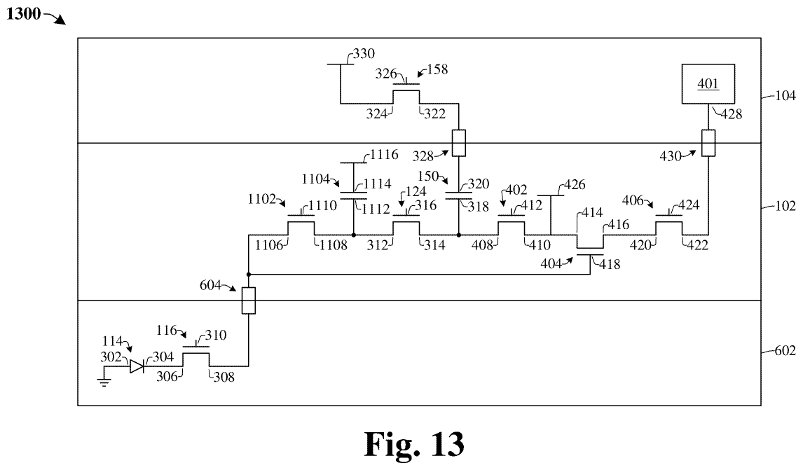

FIG. 13 illustrates a circuit diagram 1300 of some embodiments of the integrated chip of FIG. 6 in which the sixth pixel transistor 1102 and the second LOFIC 1104 are on the first semiconductor chip 102 and coupled between the transfer transistor 116 and the first pixel transistor 124.

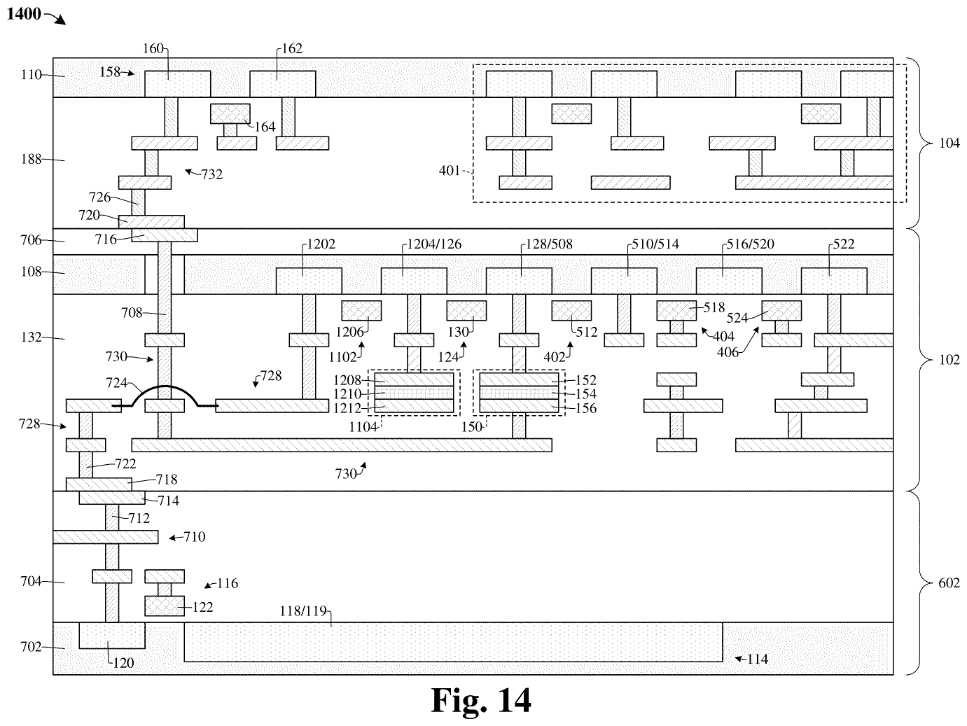

FIG. 14 illustrates a cross-sectional view 1400 of some embodiments of the integrated chip of FIG. 13 (e.g., the integrated chip of FIG. 7 in which the sixth pixel transistor 1102 and the second LOFIC 1104 are on the first semiconductor chip 102 and coupled between the transfer transistor 116 and the first pixel transistor 124).

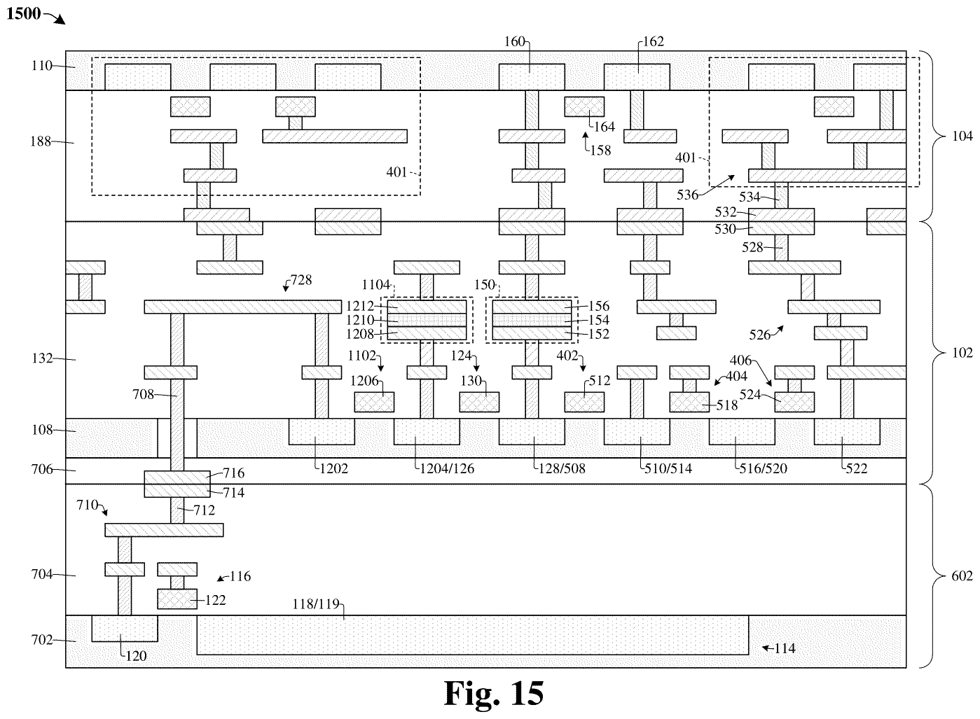

FIG. 15 illustrates a cross-sectional view 1500 of some other embodiments of the integrated chip of FIG. 13 (e.g., the integrated chip of FIG. 8 in which the sixth pixel transistor 1102 and the second LOFIC 1104 are on the first semiconductor chip 102 and coupled between the transfer transistor 116 and the first pixel transistor 124).

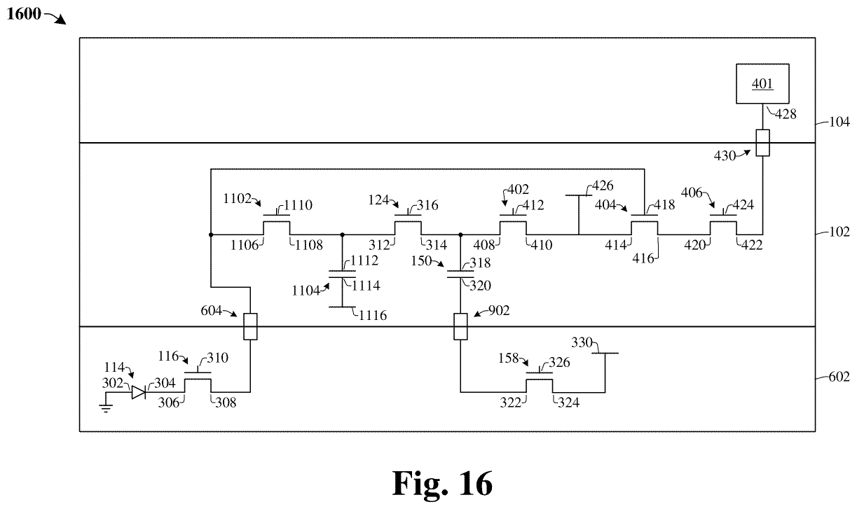

FIG. 16 illustrates a circuit diagram 1600 of some embodiments of the integrated chip of FIG. 9 in which the sixth pixel transistor 1102 and the second LOFIC 1104 are on the first semiconductor chip 102 and coupled between the transfer transistor 116 and the first pixel transistor 124.

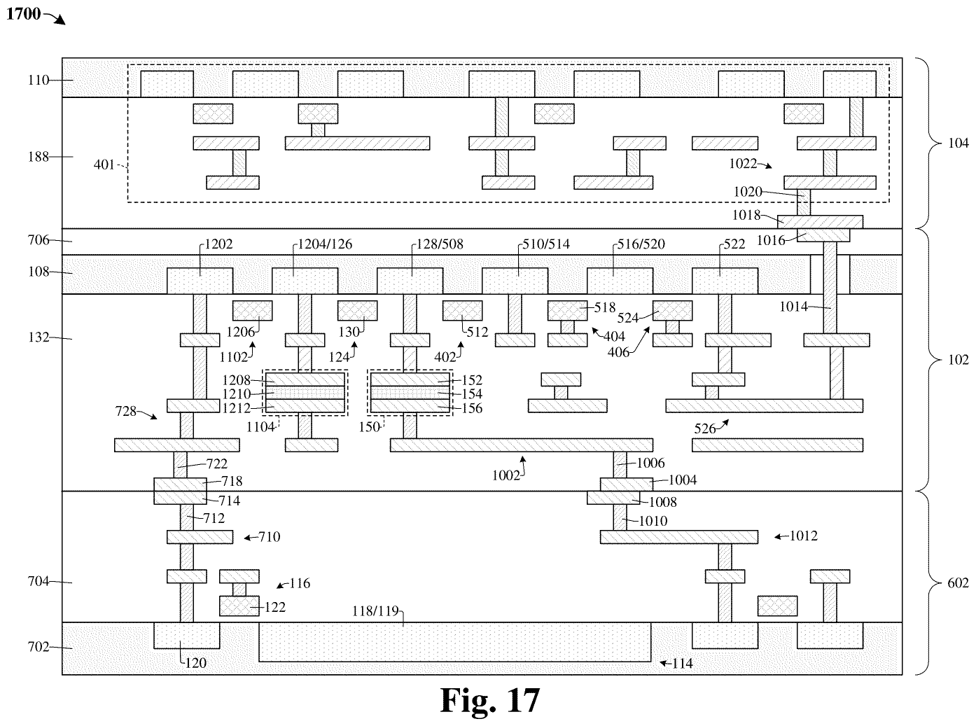

FIG. 17 illustrates a cross-sectional view 1700 of some embodiments of the integrated chip of FIG. 16 (e.g., the integrated chip of FIG. 10 in which the sixth pixel transistor 1102 and the second LOFIC 1104 are on the first semiconductor chip 102 and coupled between the transfer transistor 116 and the first pixel transistor 124).

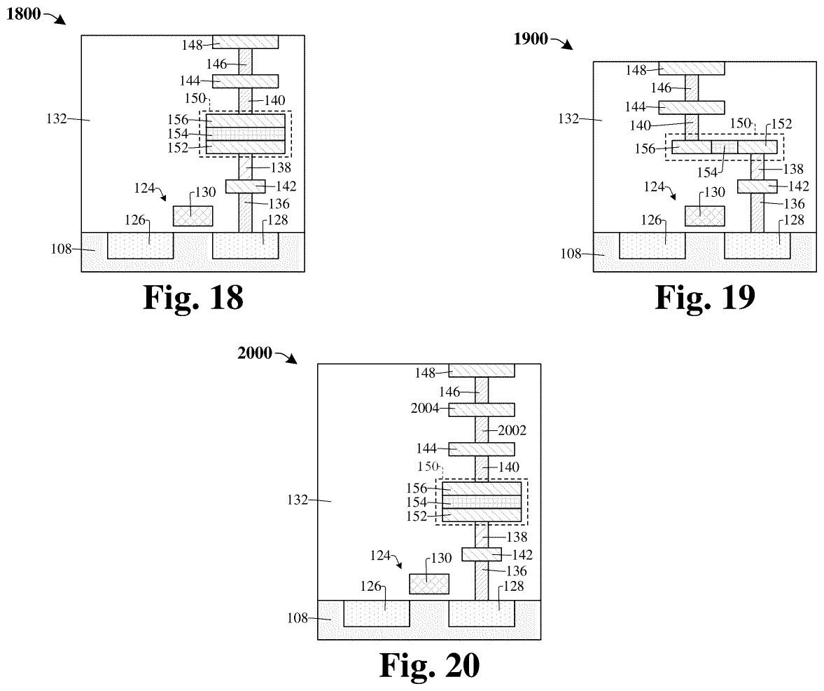

FIGS. 18-20 illustrate cross-sectional views 1800-2000 of various embodiments of the first LOFIC 150.

In some embodiments (e.g., as illustrated in FIG. 18), the first LOFIC 150 is a metal-insulator-metal (MIM) capacitor in which the first electrode layer 152, the dielectric layer 154, and the second electrode layer 156 are vertically stacked on top of one another. In some embodiments, conducive line 144 is a “top” level line and conductive via 140 is a “top” level via of the first semiconductor chip 102. For example, bonding contact 146 directly contacts conductive line 144, conductive line 144 directly contacts conductive via 140, and conductive via 140 directly contacts the second electrode layer 156 of the first LOFIC 150.

In some embodiments (e.g., as illustrated in FIG. 19), the first LOFIC 150 is a metal-oxide-metal (MOM) capacitor in which the second electrode layer 156 is laterally spaced from the first electrode layer 152, and the dielectric layer 154 is laterally between the first electrode layer 152 and the second electrode layer 156.

In some embodiments (e.g., as illustrated in FIG. 20), conductive line 144 and conductive via 140 are below the top line and top via levels. For example, conductive via 140 directly contacts the second electrode 156, conductive line 144 directly contacts conductive via 140, and one or more additional conductive interconnects (e.g., conductive via 2002 and conductive line 2004) are electrically and physically between conductive line 144 and bonding contact 146. Although the first LOFIC 150 is illustrated as a MIM capacitor in FIG. 20, it will be appreciated that in some embodiments, the first LOFIC 150 of FIG. 20 could alternatively be a MOM capacitor.

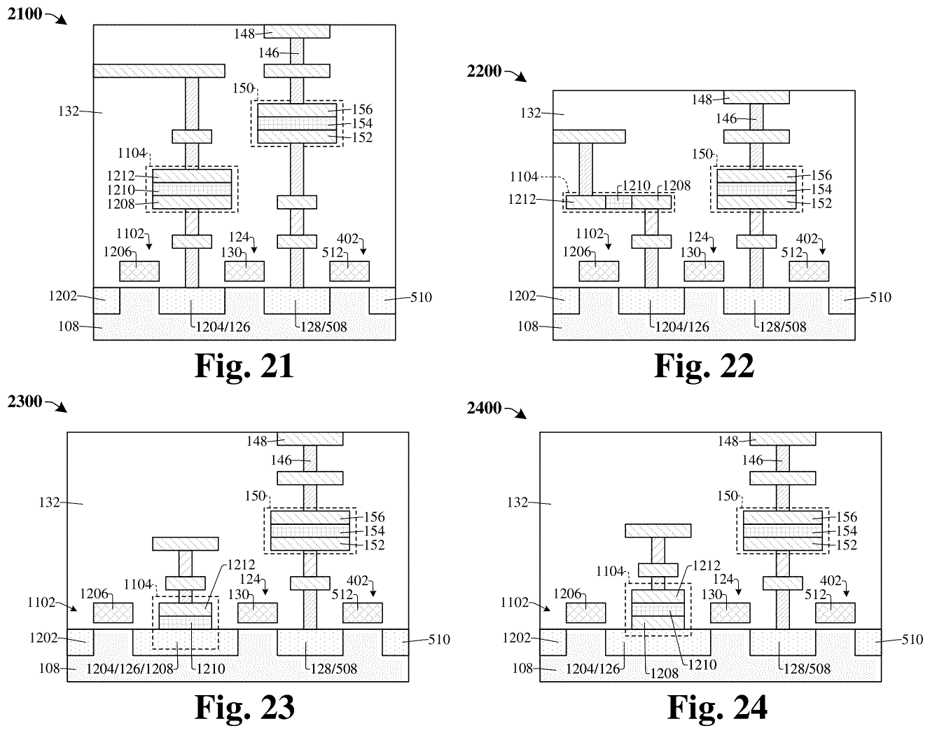

FIGS. 21-24 illustrate cross-sectional views 2100-2400 of various embodiments of the first LOFIC 150 and the second LOFIC 1104.

In some embodiments (e.g., as illustrated in FIG. 21), the second LOFIC 1104 is a MIM capacitor in which the first electrode layer 1208, the dielectric layer 1210, and the second electrode layer 1212 are vertically stacked on top of one another. In some embodiments, the second LOFIC 1104 is at a different height (e.g., from the first semiconductor substrate 108) than the first LOFIC 150. For example, in some embodiments, the first LOFIC 150 is above the second LOFIC 1104.

In some embodiments (e.g., as illustrated in FIG. 22), the second LOFIC 1104 is a MOM capacitor in which the second electrode layer 1212 is laterally spaced from the first electrode layer 1208, and the dielectric layer 1210 is laterally between the first electrode layer 1208 and the second electrode layer 1212.

In some embodiments (e.g., as illustrated in FIG. 23), the second LOFIC is a metal-oxide-semiconductor (MOS) capacitor in which source/drain 1204 and/or source/drain 126 form the first electrode layer 1208, the dielectric layer 1210 is on source/drain 1204 and/or source/drain 126, and the second electrode layer 1212 is on the dielectric layer 1210. In some embodiments, the second electrode layer 1212 comprises a metal. In some other embodiments, the second electrode layer comprises polysilicon or some other suitable material.

In some embodiments (e.g., as illustrated in FIG. 24), the first electrode layer 1208 is on source/drain 1204 and/or source/drain 126, the dielectric layer 1210 is over the first electrode layer 1208, and the second electrode layer 1212 is over the dielectric layer 1210. In some embodiments, the first electrode layer 1208 and the second electrode layer 1212 comprise polysilicon or some other suitable material.

Although the first LOFIC 150 is illustrated as a MIM capacitor in FIGS. 21-24, it will be appreciated that in some embodiments, the first LOFIC 150 of FIGS. 21-24 could alternatively be a MOM capacitor.

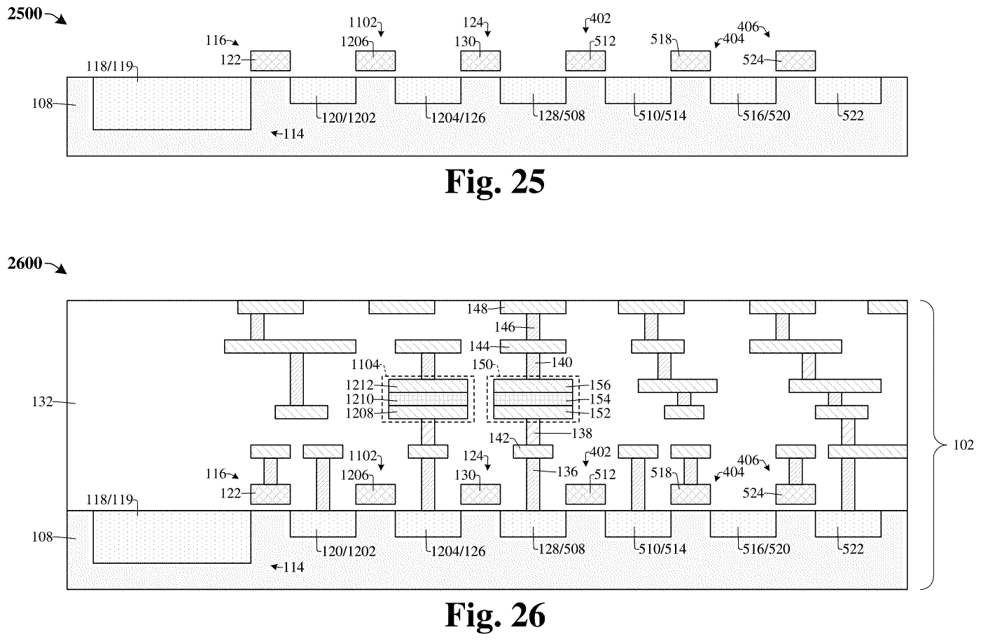

FIGS. 25-29 illustrate cross-sectional views 2500-2900 of some embodiments of a method for forming an integrated chip comprising a first LOFIC 150 on a first semiconductor chip 102 and a pixel transistor 158 on a separate chip bonded to the first semiconductor chip 102.

As shown in cross-sectional view 2500 of FIG. 25, a photodetector 114, a transfer transistor 116, and pixel transistors 124, 402, 404, 406 are formed along a first semiconductor substrate 108 of a first semiconductor chip 102. In some embodiments, pixel transistor 1102 is also formed along the first semiconductor substrate 108.

As shown in cross-sectional view 2600 of FIG. 26, a dielectric structure 132 and conductive interconnects are formed over the first semiconductor substrate 108 and on the first semiconductor chip 102. In addition, a first LOFIC 150 is formed over the first semiconductor substrate 108 and on the first semiconductor chip 102. In some embodiments, a second LOFIC 1104 is also formed over the first semiconductor substrate 108 and on the first semiconductor chip 102.

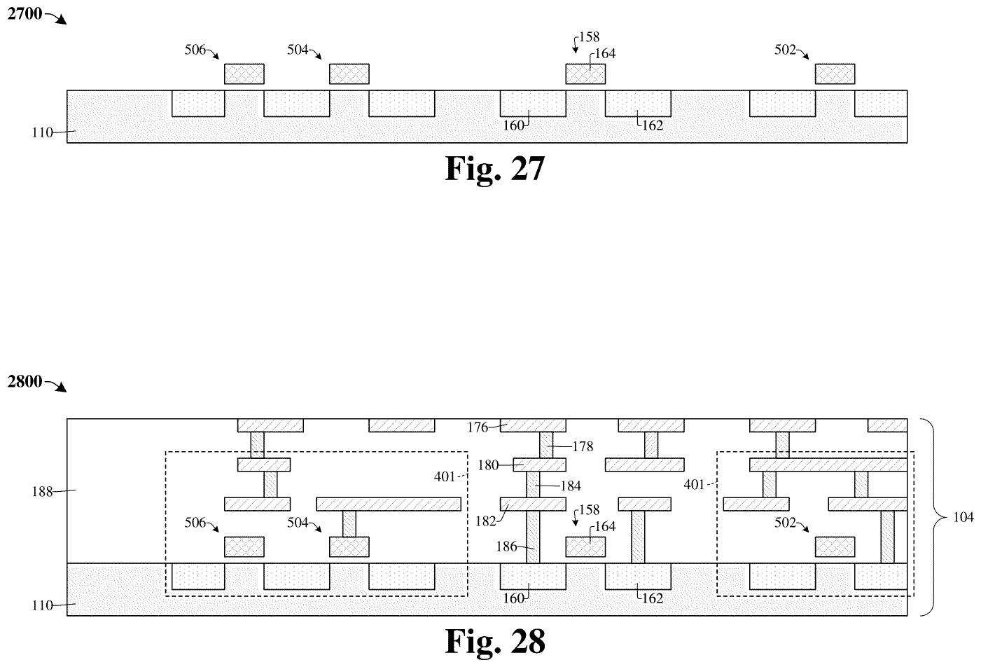

As shown in cross-sectional view 2700 of FIG. 27, a pixel transistor 158 and ASIC transistors (e.g., transistors 502, 504, 506) are formed along a second semiconductor substrate 110 of a second semiconductor chip 104.

As shown in cross-sectional view 2800 of FIG. 28, a dielectric structure 188 and conductive interconnects are formed over the second semiconductor substrate 110 and on the second semiconductor chip 104. In addition, a remainder of the ASIC 401 is formed on the second semiconductor chip 104.

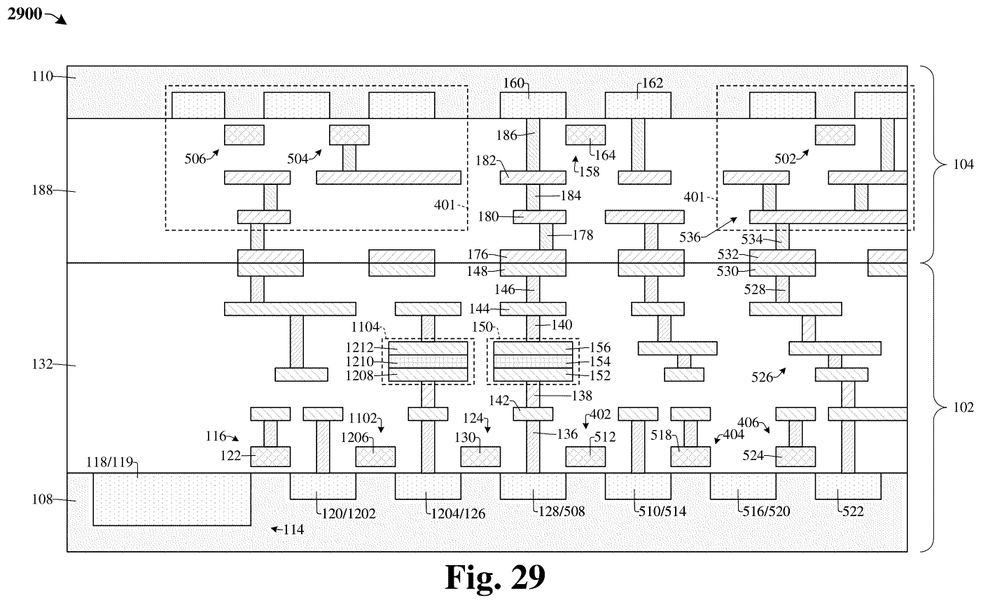

As shown in cross-sectional view 2900 of FIG. 29, the first semiconductor chip 102 and the second semiconductor chip 104 are bonded together along the dielectric structures 132, 188 of the first and second semiconductor chips and along the bonding pads (e.g., 148, 176 and 530, 532) of the first and second semiconductor chips. For example, dielectric structure 132 and dielectric structure 188 are bonded together. In addition, bonding pads on the first semiconductor chip 102 and bonding pads on the second semiconductor chip 104 are bonded together. In some embodiments, the bonding comprises a direct bonding process, a fusion bonding process, or some other suitable process.

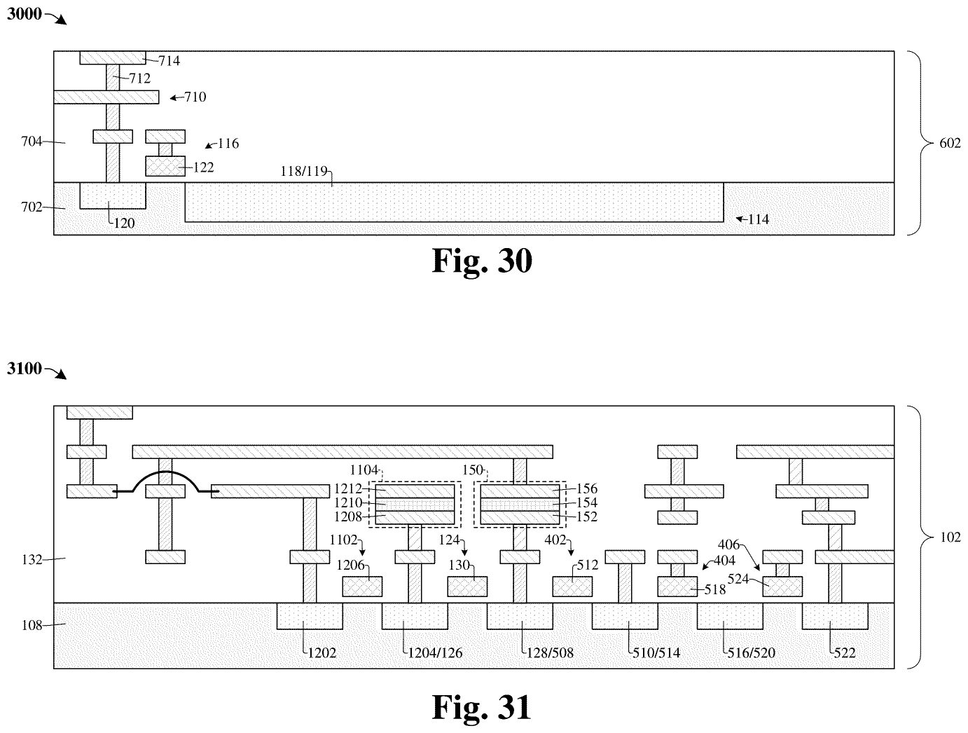

FIGS. 30-35 illustrate cross-sectional views 3000-3500 of some other embodiments of a method for forming an integrated chip comprising a first LOFIC 150 on a first semiconductor chip 102 and a pixel transistor 158 on a separate chip bonded to the first semiconductor chip 102.

As shown in cross-sectional view 3000 of FIG. 30, a photodetector 114 and a transfer transistor 116 are formed along a third semiconductor substrate 702 of a third semiconductor chip 602. In addition, a dielectric structure 704, conductive interconnects 710, bonding contact 712, and bonding pad 714 are formed over the third semiconductor substrate 702 and on the third semiconductor chip 602.

As shown in cross-sectional view 3100 of FIG. 31, pixel transistors 124, 402, 404, 406 are formed along a first semiconductor substrate 108 of a first semiconductor chip 102. In some embodiments, pixel transistor 1102 is formed along the first semiconductor substrate 108. Further, a dielectric structure 132 and conductive interconnects are formed over the first semiconductor substrate 108 and on the first semiconductor chip 102. Furthermore, a first LOFIC 150 is formed over the first semiconductor substrate 108 and on the first semiconductor chip 102. In some embodiments, a second LOFIC 1104 is also formed over the first semiconductor substrate 108 and on the first semiconductor chip 102.

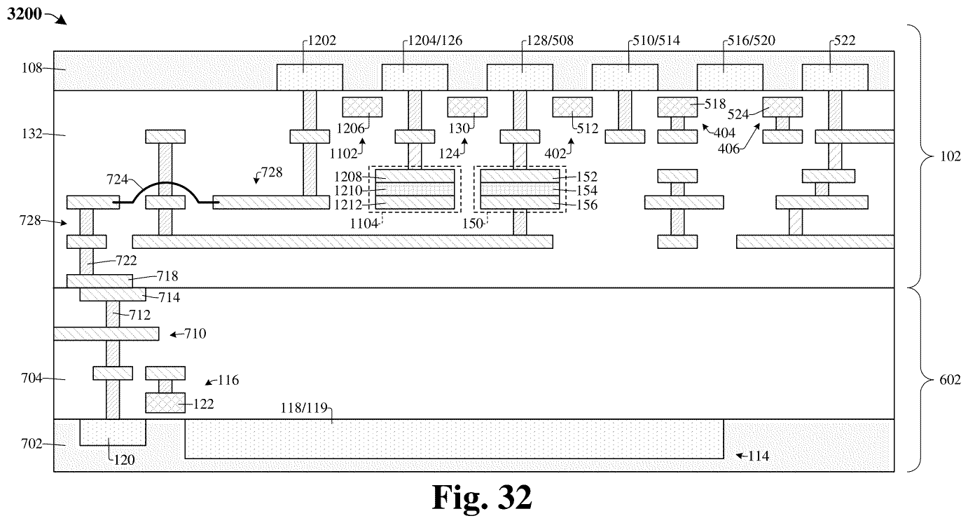

As shown in cross-sectional view 3200 of FIG. 32, the first semiconductor chip 102 and the third semiconductor chip 602 are bonded together along the dielectric structures 132, 704 and along bonding pads 718, 714. In some embodiments, the bonding comprises a direct bonding process, a fusion bonding process, or some other suitable process. In addition, in some embodiments, the first semiconductor substrate 108 is thinned from the backside. In some embodiments, the thinning comprises an etching process, a chemical mechanical planarization (CMP) process, or some other suitable process.

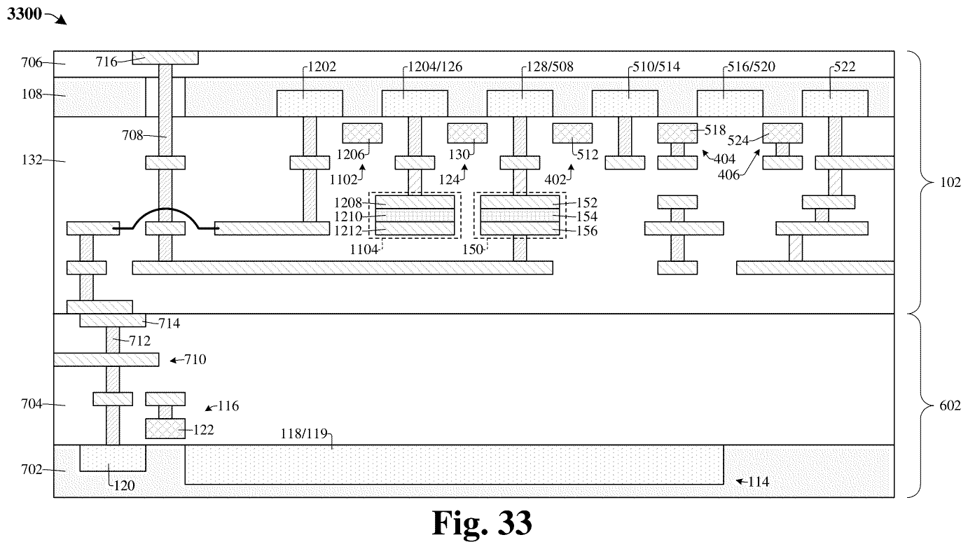

As shown in cross-sectional view 3300 of FIG. 33, a backside dielectric layer 706 is formed along the backside of the first semiconductor substrate 108 and on the first semiconductor chip 102. Further, a TSV 708 is formed on the first semiconductor chip 102 and extends through the first semiconductor substrate 108. Furthermore, bonding pad(s) 716 are formed along the backside dielectric layer 706 and on the first semiconductor chip 102.

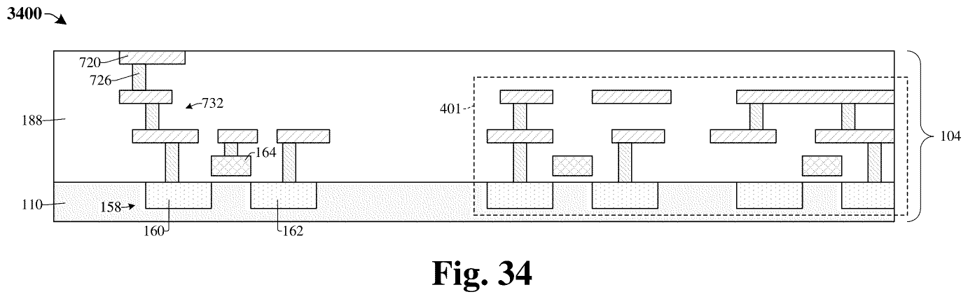

As shown in cross-sectional view 3400 of FIG. 34, a pixel transistor 158 and an ASIC 401 are formed along a second semiconductor substrate 110 of a second semiconductor chip 104. In addition, a dielectric structure 188, conductive interconnects 732, bonding contact 726, and bonding pad 720 are formed over the second semiconductor substrate 110 and on the second semiconductor chip 104.

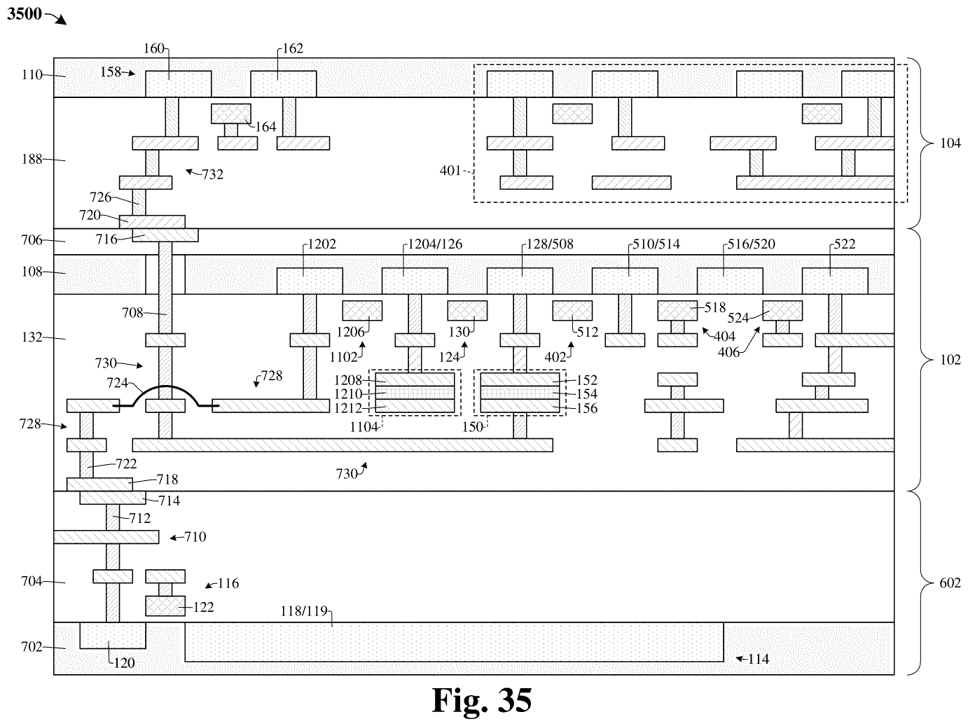

As shown in cross-sectional view 3500 of FIG. 35, the first semiconductor chip 102 and the second semiconductor chip 104 are bonded together along the dielectric structures 132, 188 and along the bonding pads 716, 720. In some embodiments, the bonding comprises a direct bonding process, a fusion bonding process, or some other suitable process.

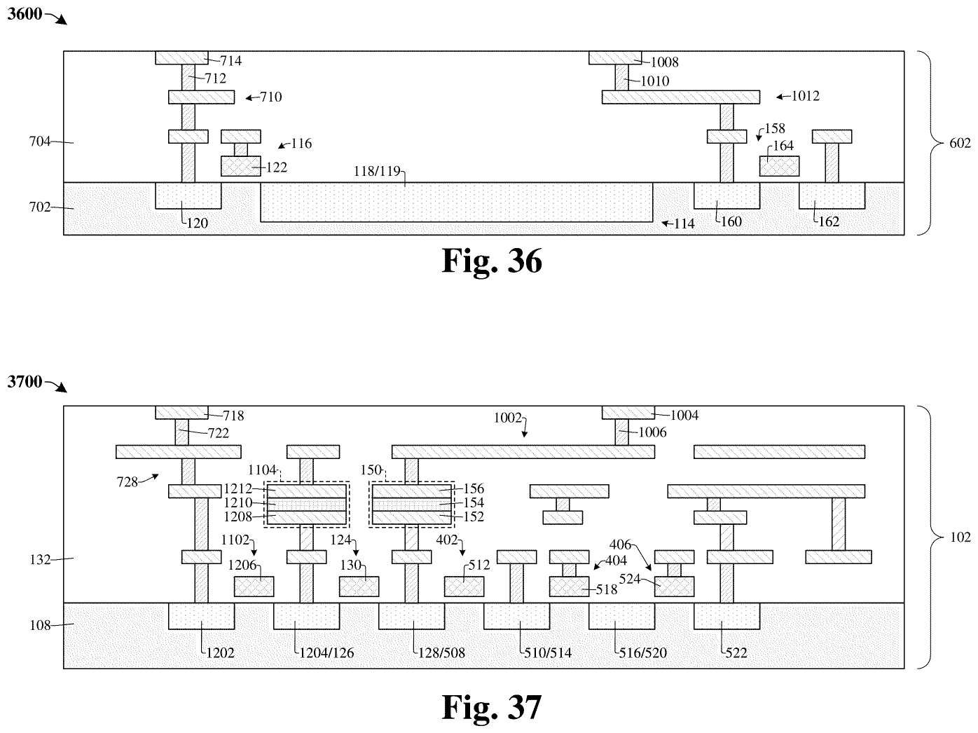

FIGS. 36-40 illustrate cross-sectional views 3600-4000 of some other embodiments of a method for forming an integrated chip comprising a first LOFIC 150 on a first semiconductor chip 102 and a pixel transistor 158 on a separate chip bonded to the first semiconductor chip 102. Although FIGS. 25-40 are described in relation to methods, it will be appreciated that the structures disclosed in FIGS. 25-40 are not limited to such methods, but instead may stand alone as structures independent of the methods.

As shown in cross-sectional view 3600 of FIG. 36, photodetector 114 and transfer transistor 116 are formed along a third semiconductor substrate 702 of a third semiconductor chip 602. Further, pixel transistor 158 is formed along the third semiconductor substrate 702 and on the third semiconductor chip 602. Furthermore, a dielectric structure 704, conductive interconnects 710, 1012, bonding contacts 712, 1010, and bonding pads 714, 1008 are formed over the third semiconductor substrate 702 and on the third semiconductor chip 602.

As shown in cross-sectional view 3700 of FIG. 37, pixel transistors 124, 402, 404, 406 are formed along a first semiconductor substrate 108 of a first semiconductor chip 102. In some embodiments, pixel transistor 1102 is also formed along the first semiconductor substrate 108. Further, a dielectric structure 132, conductive interconnects, bonding contacts 722, 1006, and bonding pads 718, 1004 are formed over the first semiconductor substrate 108 and on the first semiconductor chip 102. Furthermore, a first LOFIC 150 is formed over the first semiconductor substrate 108 and on the first semiconductor chip 102. In some embodiments, a second LOFIC 1104 is also formed over the first semiconductor substrate 108 and on the first semiconductor chip 102.

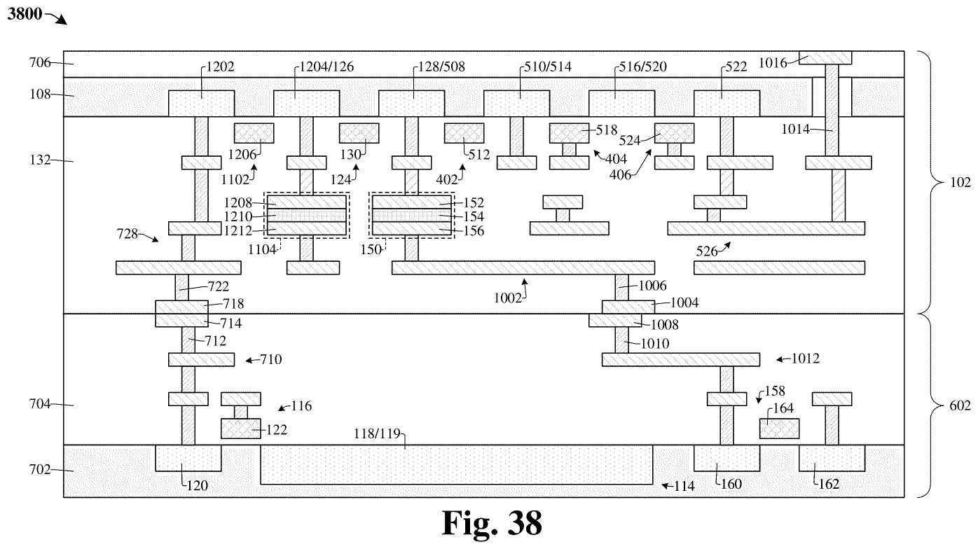

As shown in cross-sectional view 3800 of FIG. 38, the first semiconductor chip 102 and the third semiconductor chip 602 are bonded together along the dielectric structures 132, 704 and along the bonding pads 718, 714, 1004, 1008. In some embodiments, the bonding comprises a direct bonding process, a fusion bonding process, or some other suitable process. In some embodiments, the first semiconductor substrate 108 is thinned from the backside. In some embodiments, the thinning comprises an etching process, a CMP process, or some other suitable process. A backside dielectric layer 706 is formed along the backside of the first semiconductor substrate 108 and on the first semiconductor chip 102. A TSV 1014 is formed extend through the first semiconductor substrate 108 and on the first semiconductor chip 102. Bonding pad(s) 1016 are formed along the backside dielectric layer 706 and on the first semiconductor chip 102.

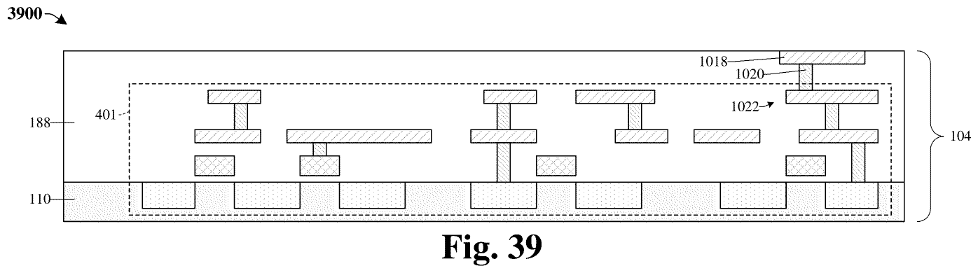

As shown in cross-sectional view 3900 of FIG. 39, an ASIC 401 is formed along a second semiconductor substrate 110 of a second semiconductor chip 104. In addition, a dielectric structure 188, conductive interconnects 1022, bonding contact 1020, and bonding pad 1018 are formed over the second semiconductor substrate 110 and on the second semiconductor chip 104.

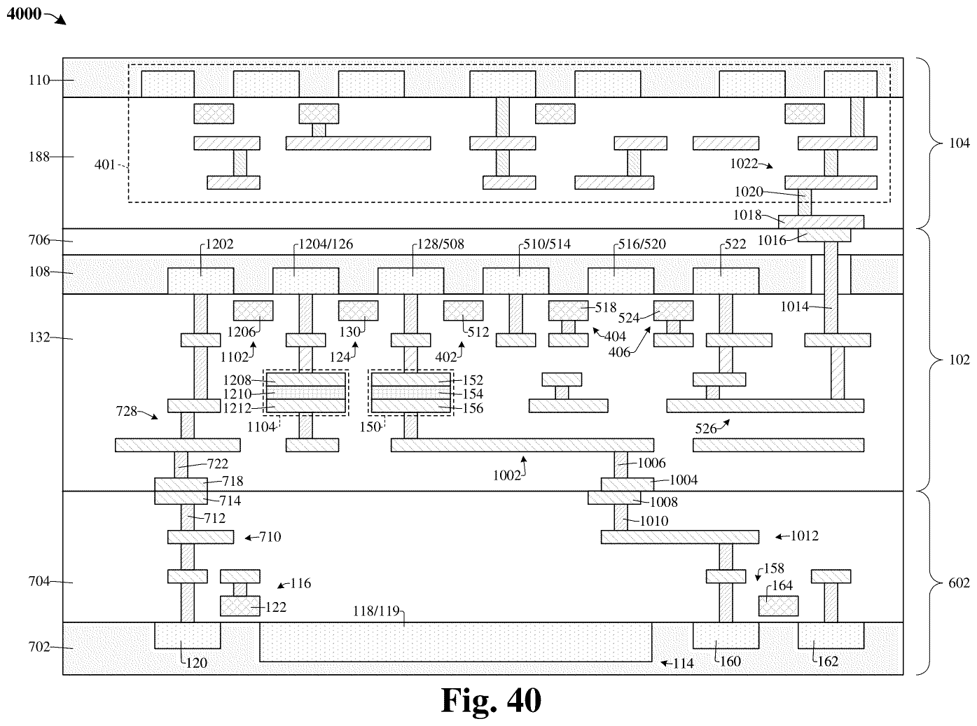

As shown in cross-sectional view 4000 of FIG. 40, the first semiconductor chip 102 and the second semiconductor chip 104 are bonded together along the dielectric structures 132, 188 and along the bonding pads 1016, 1018. In some embodiments, the bonding comprises a direct bonding process, a fusion bonding process, or some other suitable process.

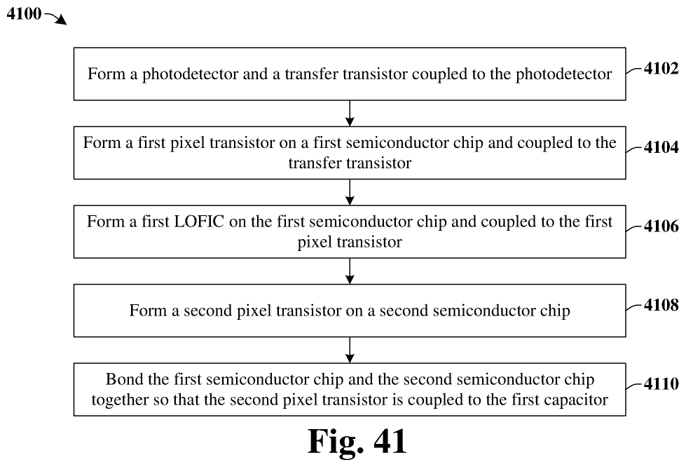

FIG. 41 illustrates a flow diagram of some embodiments of a method 4100 for forming an integrated chip comprising a first capacitor on a first semiconductor chip and a pixel transistor on a separate chip bonded to the first semiconductor chip. While method 4100 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 4102, form a photodetector and a transfer transistor coupled to the photodetector. FIG. 25 illustrates a cross-sectional view 2500 of some embodiments corresponding to block 4102. FIG. 30 illustrates a cross-sectional view 3000 of some other embodiments corresponding to block 4102. FIG. 36 illustrates a cross-sectional view 3600 of some other embodiments corresponding to block 4102.

At block 4104, form a first pixel transistor on a first semiconductor chip and coupled to the transfer transistor. FIG. 25 illustrates a cross-sectional view 2500 of some embodiments corresponding to block 4104. FIG. 31 illustrates a cross-sectional view 3100 of some other embodiments corresponding to block 4104. FIG. 37 illustrates a cross-sectional view 3700 of some other embodiments corresponding to block 4104.

At block 4106, form a first LOFIC on the first semiconductor chip and coupled to the first pixel transistor. FIG. 26 illustrates a cross-sectional view 2600 of some embodiments corresponding to block 4106. FIG. 31 illustrates a cross-sectional view 3100 of some other embodiments corresponding to block 4106. FIG. 37 illustrates a cross-sectional view 3700 of some other embodiments corresponding to block 4106.

At block 4108, form a second pixel transistor on a second semiconductor chip. FIG. 27 illustrates a cross-sectional view 2700 of some embodiments corresponding to block 4108. FIG. 34 illustrates a cross-sectional view 3400 of some other embodiments corresponding to block 4108. FIG. 36 illustrates a cross-sectional view 3600 of some other embodiments corresponding to block 4108.

At block 4110, bond the first semiconductor chip and the second semiconductor chip together so that the second pixel transistor is coupled to the first capacitor. FIG. 29 illustrates a cross-sectional view 2900 of some embodiments corresponding to block 4110. FIG. 35 illustrates a cross-sectional view 3500 of some other embodiments corresponding to block 4110. FIG. 38 illustrates a cross-sectional view 3800 of some other embodiments corresponding to block 4110.

Thus, the present disclosure relates to an integrated chip and a method for forming the integrated chip, the integrated chip comprising a first LOFIC on a first semiconductor chip and a pixel transistor coupled to the first LOFIC and on a separate chip bonded to the first semiconductor chip.

Accordingly, in some embodiments, the present disclosure relates to an integrated chip including a photodetector, a transfer transistor, a first pixel transistor, a first capacitor, a second pixel transistor, and a bonding structure. The photodetector has a first terminal. The transfer transistor has a first terminal, a second terminal, and a control terminal. The first terminal of the transfer transistor is coupled to the first terminal of the photodetector. The first pixel transistor is on a first semiconductor chip. The first pixel transistor has a first terminal, a second terminal, and a control terminal. The first terminal of the first pixel transistor is coupled to the second terminal of the transfer transistor. The first capacitor is on the first semiconductor chip. The first capacitor has a first terminal and a second terminal. The first terminal of the first capacitor is coupled to the second terminal of the first pixel transistor. The second pixel transistor is on a second semiconductor chip bonded to the first semiconductor chip. The second pixel transistor has a first terminal, a second terminal, and a control terminal. The second terminal of the second pixel transistor is coupled to a first reference voltage terminal. The bonding structure is at an interface where the first semiconductor chip and the second semiconductor chip are bonded together. The bonding structure couples the second terminal of the first capacitor to the first terminal of the second pixel transistor. In some embodiments, the photodetector and the transfer transistor are on the first semiconductor chip, and the integrated chip further includes an application specific integrated circuit on the second semiconductor chip. The control terminal of the transfer transistor, the control terminal of the first pixel transistor, and the control terminal of the second pixel transistor are coupled to the application specific integrated circuit. In some embodiments, the photodetector and the transfer transistor are on the second semiconductor chip, and the integrated chip further includes an application specific integrated circuit on a third semiconductor chip bonded to the first semiconductor chip. The control terminal of the transfer transistor, the control terminal of the first pixel transistor, and the control terminal of the second pixel transistor are coupled to the application specific integrated circuit. In some embodiments, the photodetector and the transfer transistor are on a third semiconductor chip bonded to the first semiconductor chip, and the integrated chip further includes an application specific integrated circuit on the second semiconductor chip. The control terminal of the transfer transistor, the control terminal of the first pixel transistor, and the control terminal of the second pixel transistor are coupled to the application specific integrated circuit. In some embodiments, the integrated chip further includes a third pixel transistor, a fourth pixel transistor, a fifth pixel transistor, and an application specific integrated circuit. The third pixel transistor is on the first semiconductor chip. The third pixel transistor has a first terminal, a second terminal, and a control terminal. The first terminal of the third pixel transistor is coupled to the second terminal of the first pixel transistor and the first terminal of the first capacitor. The second terminal of the third pixel transistor is coupled to a first supply voltage terminal. The fourth pixel transistor is on the first semiconductor chip. The fourth pixel transistor has a first terminal, a second terminal, and a control terminal. The first terminal of the fourth pixel transistor is coupled to the second terminal of the third pixel transistor and the first supply voltage terminal. The control terminal of the fourth pixel transistor is coupled to the second terminal of the transfer transistor. The fifth pixel transistor is on the first semiconductor chip. The fifth pixel transistor has a first terminal, a second terminal, and a control terminal. The first terminal of the fifth pixel transistor is coupled to the second terminal of the fourth pixel transistor. The application specific integrated circuit is coupled to the second terminal of the fifth pixel transistor. In some embodiments, the integrated chip further includes a sixth pixel transistor and a second capacitor. The sixth pixel transistor is on the first semiconductor chip and coupled between the transfer transistor and the first pixel transistor. The sixth pixel transistor has a first terminal, a second terminal, and a control terminal. The first terminal of the sixth pixel transistor is coupled to the second terminal of the transfer transistor. The second terminal of the sixth pixel transistor is coupled to the first terminal of the first pixel transistor. The second capacitor is on the first semiconductor chip. The second capacitor has a first terminal and a second terminal. The first terminal of the second capacitor is coupled to the second terminal of the sixth pixel transistor and the first terminal of the first pixel transistor. The second terminal of the second capacitor is coupled to a second reference voltage terminal.

In other embodiments, the present disclosure relates to an integrated chip including a photodetector, a transfer transistor, a first pixel transistor, a first lateral overflow integration capacitor (LOFIC), a first bonding pad, a second bonding pad, and a second pixel transistor. The photodetector and transfer transistor are on a first semiconductor chip and disposed along a first semiconductor substrate, on a second semiconductor chip and disposed along a second semiconductor substrate, or on a third semiconductor chip and disposed along a third semiconductor substrate. The transfer transistor includes a first source/drain, a second source/drain, and a gate. The first source/drain of the transfer transistor is coupled to the photodetector. The first pixel transistor is on the first semiconductor chip and disposed along the first semiconductor substrate. The first pixel transistor includes a first source/drain, a second source/drain, and a gate. The first source/drain of the first pixel transistor is coupled to the second source/drain of the transfer transistor. The first LOFIC is on the first semiconductor chip. The first LOFIC includes a first electrode, a second electrode, and a dielectric between the first electrode and the second electrode. The first electrode is coupled to the second source/drain of the first pixel transistor by a first conductive interconnect on the first semiconductor chip. The first bonding pad is on the first semiconductor chip and coupled to the second electrode of the first LOFIC by a second conductive interconnect on the first semiconductor chip. The second bonding pad is on the second semiconductor chip. The second bonding pad is bonded and coupled to the first bonding pad. The second pixel transistor is on the second semiconductor chip and disposed along the second semiconductor substrate. The second pixel transistor includes a first source/drain, a second source/drain, and a gate. The second source/drain of the second pixel transistor is coupled to a first reference voltage terminal by a fourth conductive interconnect on the second semiconductor chip. The first source/drain of the second pixel transistor is coupled to the second bonding pad by a third conductive interconnect on the second semiconductor chip. In some embodiments, the integrated chip further includes a third pixel transistor, a fourth pixel transistor, a fifth pixel transistor, and an application specific integrated circuit. The third pixel transistor is on the first semiconductor chip and disposed along the first semiconductor substrate. The third pixel transistor includes a first source/drain, a second source/drain, and a gate. The first source/drain of the third pixel transistor is coupled to the second source/drain of the first pixel transistor and the first electrode of the first LOFIC. The second source/drain of the third pixel transistor is coupled to a supply voltage terminal. The fourth pixel transistor is on the first semiconductor chip and disposed along the first semiconductor substrate. The fourth pixel transistor includes a first source/drain, a second source/drain, and a gate. The first source/drain of the fourth pixel transistor is coupled to the second source/drain of the third pixel transistor and the supply voltage terminal. The gate of the fourth pixel transistor is coupled to the second source/drain of the transfer transistor. The fifth pixel transistor is on the first semiconductor chip and disposed along the first semiconductor substrate. The fifth pixel transistor includes a first source/drain, a second source/drain, and a gate. The first source/drain of the fifth pixel transistor is coupled to the second source/drain of the fourth pixel transistor. The application specific integrated circuit is coupled to the second source/drain of the fifth pixel transistor. In some embodiments, the integrated chip further includes a sixth pixel transistor and a second LOFIC. The sixth pixel transistor is on the first semiconductor chip and disposed along the first semiconductor substrate. The sixth pixel transistor includes a first source/drain, a second source/drain, and a gate. The first source/drain of the sixth pixel transistor is coupled to the second source/drain of the transfer transistor. The second source/drain of the sixth pixel transistor is coupled to the first source/drain of the first pixel transistor. The second LOFIC is on the first semiconductor chip. The second LOFIC includes a first electrode, a second electrode, and a dielectric between the first electrode and the second electrode. The first electrode of the second LOFIC is coupled to the second source/drain of the sixth pixel transistor and the first source/drain of the first pixel transistor by a fifth conductive interconnect on the first semiconductor chip. The second electrode of the second LOFIC is coupled to a second reference voltage terminal by a sixth conductive interconnect on the first semiconductor chip. In some embodiments, the gate of the transfer transistor, the gate of the first pixel transistor, the gate of the second pixel transistor, the gate of the third pixel transistor, the gate of the fifth pixel transistor, and the gate of the sixth pixel transistor are coupled to the application specific integrated circuit. In some embodiments, the photodetector and the transfer transistor are on the first semiconductor chip and disposed along the first semiconductor substrate. The application specific integrated circuit is on the second semiconductor chip, and the integrated chip further includes a third bonding pad and a fourth bonding pad. The third bonding pad is on the first semiconductor chip and coupled to the second source/drain of the fifth pixel transistor by a seventh conductive interconnect on the first semiconductor chip. The fourth bonding pad is on the second semiconductor chip and coupled to the application specific integrated circuit by an eighth conductive interconnect on the second semiconductor chip. The fourth bonding pad is bonded and coupled to the third bonding pad. In some embodiments, the photodetector and the transfer transistor are on the second semiconductor chip and disposed along the second semiconductor substrate. The application specific integrated circuit is on the third semiconductor chip, and the integrated chip further includes a third bonding pad, a fourth bonding pad, a fifth bonding pad, and a sixth bonding pad. The third bonding pad is on the first semiconductor chip and coupled to the second source/drain of the fifth pixel transistor by a seventh conductive interconnect on the first semiconductor chip. The fourth bonding pad is on the third semiconductor chip and coupled to the application specific integrated circuit by an eighth conductive interconnect on the third semiconductor chip. The fourth bonding pad is bonded and coupled to the third bonding pad. The fifth bonding pad is on the first semiconductor chip and coupled to the first source/drain of the sixth pixel transistor by a nineth conductive interconnect on the first semiconductor chip. The sixth bonding pad is on the second semiconductor chip and coupled to the second source/drain of the transfer transistor by a tenth conductive interconnect on the second semiconductor chip. The sixth bonding pad is bonded and coupled to the fifth bonding pad. In some embodiments, the photodetector and the transfer transistor are on the third semiconductor chip and disposed along the third semiconductor substrate. The application specific integrated circuit is on the second semiconductor chip, and the integrated chip further includes a third bonding pad, a fourth bonding pad, a fifth bonding pad, and a sixth bonding pad. The third bonding pad is on the first semiconductor chip and coupled to the second source/drain of the fifth pixel transistor by a seventh conductive interconnect on the first semiconductor chip. The fourth bonding pad is on the second semiconductor chip and coupled to the application specific integrated circuit by an eighth conductive interconnect on the second semiconductor chip. The fourth bonding pad is bonded and coupled to the third bonding pad. The fifth bonding pad is on the first semiconductor chip and coupled to the first source/drain of the sixth pixel transistor by a nineth conductive interconnect on the first semiconductor chip. The sixth bonding pad is on the third semiconductor chip and coupled to the second source/drain of the transfer transistor by a tenth conductive interconnect on the third semiconductor chip. The sixth bonding pad is bonded and coupled to the fifth bonding pad. In some embodiments, the second conductive interconnect is a top conductive line on the first semiconductor chip, and the integrated chip further includes a first bonding contact and a top conductive via. The first bonding contact is on the first semiconductor chip and extends from the first bonding pad to the top conductive line. The top conductive via is on the first semiconductor chip and extends from the second conductive interconnect to the second electrode of the first LOFIC.

In yet other embodiments, the present disclosure relates to a method for forming an integrated chip. The method includes forming a photodetector and transfer transistor. The transfer transistor includes a first source/drain, a second source/drain, and a gate. The first source/drain of the transfer transistor is coupled to the photodetector. The method includes forming a first pixel transistor along a first semiconductor substrate of a first semiconductor chip. The first pixel transistor includes a first source/drain, a second source/drain, and a gate. The first source/drain of the first pixel transistor is coupled to the second source/drain of the transfer transistor. The method includes forming a first conductive interconnect on the first semiconductor chip and coupled to the second source/drain of the first pixel transistor. The method includes forming a first capacitor on the first semiconductor chip. The first capacitor includes a first electrode, a second electrode, and a dielectric between the first electrode and the second electrode. The first electrode is coupled to the first conductive interconnect. The method includes forming a second conductive interconnect on the first semiconductor chip and coupled to the second electrode of the first capacitor. The method includes forming a first bonding pad on the first semiconductor chip and coupled to the second conductive interconnect. The method includes forming a second pixel transistor along a second semiconductor substrate of a second semiconductor chip. The second pixel transistor includes a first source/drain, a second source/drain, and a gate. The method includes forming a third conductive interconnect on the second semiconductor chip and coupled to the first source/drain of the second pixel transistor. The method includes forming a second bonding pad on the second semiconductor chip and coupled to the third conductive interconnect. The method includes bonding the first bonding pad to the second bonding pad. The second electrode of the first capacitor is coupled to the first source/drain of the second pixel transistor by the second conductive interconnect, the first bonding pad, the second bonding pad, and the third conductive interconnect. In some embodiments, the method further includes forming a third pixel transistor along the first semiconductor substrate of the first semiconductor chip. The third pixel transistor includes a first source/drain, a second source/drain, and a gate. The first source/drain of the third pixel transistor is coupled to the second source/drain of the first pixel transistor and the first electrode of the first capacitor. The second source/drain the of the third pixel transistor is coupled to a supply voltage terminal. The method includes forming a fourth pixel transistor along the first semiconductor substrate of the first semiconductor chip. The fourth pixel transistor includes a first source/drain, a second source/drain, and a gate. The first source/drain of the fourth pixel transistor is coupled to the second source/drain of the third pixel transistor and the supply voltage terminal. The gate of the fourth pixel transistor is coupled to the second source/drain of the transfer transistor. The method includes forming a fifth pixel transistor along the first semiconductor substrate of the first semiconductor chip. The fifth pixel transistor includes a first source/drain, a second source/drain, and a gate. The first source/drain of the fifth pixel transistor is coupled to the second source/drain of the fourth pixel transistor. The method includes forming an application specific integrated circuit coupled to the second source/drain of the fifth pixel transistor. In some embodiments, the photodetector and the transfer transistor are formed along the first semiconductor substrate of the first semiconductor chip, and the application specific integrated circuit is formed on the second semiconductor chip. In some embodiments, the photodetector and the transfer transistor are formed along the second semiconductor substrate of the second semiconductor chip, and the application specific integrated circuit is formed on a third semiconductor chip. In some embodiments, the photodetector and the transfer transistor are formed along a third semiconductor substrate of a third semiconductor chip, and the application specific integrated circuit is formed on the second semiconductor chip. In some embodiments, the method includes forming a third pixel transistor along the first semiconductor substrate of the first semiconductor chip. The third pixel transistor includes a first source/drain, a second source/drain, and a gate. The first source/drain of the third pixel transistor is coupled to the second source/drain of the transfer transistor. The second source/drain of the third pixel transistor is coupled to the first source/drain of the first pixel transistor. The method includes forming a fourth conductive interconnect on the first semiconductor chip and coupled to the second source/drain of the third pixel transistor and the first source/drain of the first pixel transistor. The method includes forming a second capacitor on the first semiconductor chip. The second capacitor includes a first electrode, a second electrode, and a dielectric between the first electrode and the second electrode. The first electrode of the first capacitor is coupled to the fourth conductive interconnect.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a photodetector having a first terminal;
a transfer transistor having a first terminal, a second terminal, and a control terminal, the first terminal of the transfer transistor coupled to the first terminal of the photodetector;
a first pixel transistor on a first semiconductor chip, the first pixel transistor having a first terminal, a second terminal, and a control terminal, the first terminal of the first pixel transistor coupled to the second terminal of the transfer transistor;
a first capacitor on the first semiconductor chip, the first capacitor having a first terminal and a second terminal, the first terminal of the first capacitor coupled to the second terminal of the first pixel transistor;
a second pixel transistor on a second semiconductor chip bonded to the first semiconductor chip, the second pixel transistor having a first terminal, a second terminal, and a control terminal, the second terminal of the second pixel transistor coupled to a first reference voltage terminal; and
a bonding structure at an interface where the first semiconductor chip and the second semiconductor chip are bonded together, the bonding structure coupling the second terminal of the first capacitor to the first terminal of the second pixel transistor.

2. The integrated chip of claim 1, wherein the photodetector and the transfer transistor are on the first semiconductor chip, the integrated chip further comprising:
an application specific integrated circuit on the second semiconductor chip, wherein the control terminal of the transfer transistor, the control terminal of the first pixel transistor, and the control terminal of the second pixel transistor are coupled to the application specific integrated circuit.

3. The integrated chip of claim 1, wherein the photodetector and the transfer transistor are on the second semiconductor chip, the integrated chip further comprising:
an application specific integrated circuit on a third semiconductor chip bonded to the first semiconductor chip, wherein the control terminal of the transfer transistor, the control terminal of the first pixel transistor, and the control terminal of the second pixel transistor are coupled to the application specific integrated circuit.

4. The integrated chip of claim 1, wherein the photodetector and the transfer transistor are on a third semiconductor chip bonded to the first semiconductor chip, the integrated chip further comprising:
an application specific integrated circuit on the second semiconductor chip, wherein the control terminal of the transfer transistor, the control terminal of the first pixel transistor, and the control terminal of the second pixel transistor are coupled to the application specific integrated circuit.

5. The integrated chip of claim 1, further comprising:
a third pixel transistor on the first semiconductor chip, the third pixel transistor having a first terminal, a second terminal, and a control terminal, the first terminal of the third pixel transistor coupled to the second terminal of the first pixel transistor and the first terminal of the first capacitor, the second terminal of the third pixel transistor coupled to a first supply voltage terminal;
a fourth pixel transistor on the first semiconductor chip, the fourth pixel transistor having a first terminal, a second terminal, and a control terminal, the first terminal of the fourth pixel transistor coupled to the second terminal of the third pixel transistor and the first supply voltage terminal, the control terminal of the fourth pixel transistor coupled to the second terminal of the transfer transistor;
a fifth pixel transistor on the first semiconductor chip, the fifth pixel transistor having a first terminal, a second terminal, and a control terminal, the first terminal of the fifth pixel transistor coupled to the second terminal of the fourth pixel transistor; and
an application specific integrated circuit coupled to the second terminal of the fifth pixel transistor.

6. The integrated chip of claim 5, further comprising:
a sixth pixel transistor on the first semiconductor chip and coupled between the transfer transistor and the first pixel transistor, the sixth pixel transistor having a first terminal, a second terminal, and a control terminal, the first terminal of the sixth pixel transistor coupled to the second terminal of the transfer transistor, the second terminal of the sixth pixel transistor coupled to the first terminal of the first pixel transistor; and
a second capacitor on the first semiconductor chip, the second capacitor having a first terminal and a second terminal, the first terminal of the second capacitor coupled to the second terminal of the sixth pixel transistor and the first terminal of the first pixel transistor, the second terminal of the second capacitor coupled to a second reference voltage terminal.

7. An integrated chip comprising:
a photodetector and transfer transistor on a first semiconductor chip and disposed along a first semiconductor substrate, on a second semiconductor chip and disposed along a second semiconductor substrate, or on a third semiconductor chip and disposed along a third semiconductor substrate, the transfer transistor including a first source/drain, a second source/drain, and a gate, wherein the first source/drain of the transfer transistor is coupled to the photodetector;
a first pixel transistor on the first semiconductor chip and disposed along the first semiconductor substrate, the first pixel transistor including a first source/drain, a second source/drain, and a gate, wherein the first source/drain of the first pixel transistor is coupled to the second source/drain of the transfer transistor;
a first lateral overflow integration capacitor (LOFIC) on the first semiconductor chip, the first LOFIC including a first electrode, a second electrode, and a dielectric between the first electrode and the second electrode, wherein the first electrode is coupled to the second source/drain of the first pixel transistor by a first conductive interconnect on the first semiconductor chip;
a first bonding pad on the first semiconductor chip and coupled to the second electrode of the first LOFIC by a second conductive interconnect on the first semiconductor chip;
a second bonding pad on the second semiconductor chip, wherein the second bonding pad is bonded and coupled to the first bonding pad; and
a second pixel transistor on the second semiconductor chip and disposed along the second semiconductor substrate, the second pixel transistor including a first source/drain, a second source/drain, and a gate, the second source/drain of the second pixel transistor coupled to a first reference voltage terminal by a fourth conductive interconnect on the second semiconductor chip, the first source/drain of the second pixel transistor coupled to the second bonding pad by a third conductive interconnect on the second semiconductor chip.

8. The integrated chip of claim 7, further comprising:
a third pixel transistor on the first semiconductor chip and disposed along the first semiconductor substrate, the third pixel transistor including a first source/drain, a second source/drain, and a gate, wherein the first source/drain of the third pixel transistor is coupled to the second source/drain of the first pixel transistor and the first electrode of the first LOFIC, and wherein the second source/drain of the third pixel transistor is coupled to a supply voltage terminal;
a fourth pixel transistor on the first semiconductor chip and disposed along the first semiconductor substrate, the fourth pixel transistor including a first source/drain, a second source/drain, and a gate, wherein the first source/drain of the fourth pixel transistor is coupled to the second source/drain of the third pixel transistor and the supply voltage terminal, and wherein the gate of the fourth pixel transistor is coupled to the second source/drain of the transfer transistor;
a fifth pixel transistor on the first semiconductor chip and disposed along the first semiconductor substrate, the fifth pixel transistor including a first source/drain, a second source/drain, and a gate, wherein the first source/drain of the fifth pixel transistor is coupled to the second source/drain of the fourth pixel transistor; and
an application specific integrated circuit coupled to the second source/drain of the fifth pixel transistor.

9. The integrated chip of claim 8, further comprising:
a sixth pixel transistor on the first semiconductor chip and disposed along the first semiconductor substrate, the sixth pixel transistor including a first source/drain, a second source/drain, and a gate, the first source/drain of the sixth pixel transistor coupled to the second source/drain of the transfer transistor, the second source/drain of the sixth pixel transistor coupled to the first source/drain of the first pixel transistor; and
a second LOFIC on the first semiconductor chip, the second LOFIC including a first electrode, a second electrode, and a dielectric between the first electrode and the second electrode, wherein the first electrode of the second LOFIC is coupled to the second source/drain of the sixth pixel transistor and the first source/drain of the first pixel transistor by a fifth conductive interconnect on the first semiconductor chip, and wherein the second electrode of the second LOFIC is coupled to a second reference voltage terminal by a sixth conductive interconnect on the first semiconductor chip.

10. The integrated chip of claim 9, wherein the gate of the transfer transistor, the gate of the first pixel transistor, the gate of the second pixel transistor, the gate of the third pixel transistor, the gate of the fifth pixel transistor, and the gate of the sixth pixel transistor are coupled to the application specific integrated circuit.

11. The integrated chip of claim 9, wherein the photodetector and the transfer transistor are on the first semiconductor chip and disposed along the first semiconductor substrate, wherein the application specific integrated circuit is on the second semiconductor chip, the integrated chip further comprising:
a third bonding pad on the first semiconductor chip and coupled to the second source/drain of the fifth pixel transistor by a seventh conductive interconnect on the first semiconductor chip; and
a fourth bonding pad on the second semiconductor chip and coupled to the application specific integrated circuit by an eighth conductive interconnect on the second semiconductor chip, wherein the fourth bonding pad is bonded and coupled to the third bonding pad.

12. The integrated chip of claim 9, wherein the photodetector and the transfer transistor are on the second semiconductor chip and disposed along the second semiconductor substrate, wherein the application specific integrated circuit is on the third semiconductor chip, the integrated chip further comprising:
a third bonding pad on the first semiconductor chip and coupled to the second source/drain of the fifth pixel transistor by a seventh conductive interconnect on the first semiconductor chip;
a fourth bonding pad on the third semiconductor chip and coupled to the application specific integrated circuit by an eighth conductive interconnect on the third semiconductor chip, wherein the fourth bonding pad is bonded and coupled to the third bonding pad;
a fifth bonding pad on the first semiconductor chip and coupled to the first source/drain of the sixth pixel transistor by a nineth conductive interconnect on the first semiconductor chip; and
a sixth bonding pad on the second semiconductor chip and coupled to the second source/drain of the transfer transistor by a tenth conductive interconnect on the second semiconductor chip, wherein the sixth bonding pad is bonded and coupled to the fifth bonding pad.

13. The integrated chip of claim 9, wherein the photodetector and the transfer transistor are on the third semiconductor chip and disposed along the third semiconductor substrate, wherein the application specific integrated circuit is on the second semiconductor chip, the integrated chip further comprising:
a third bonding pad on the first semiconductor chip and coupled to the second source/drain of the fifth pixel transistor by a seventh conductive interconnect on the first semiconductor chip;
a fourth bonding pad on the second semiconductor chip and coupled to the application specific integrated circuit by an eighth conductive interconnect on the second semiconductor chip, wherein the fourth bonding pad is bonded and coupled to the third bonding pad;
a fifth bonding pad on the first semiconductor chip and coupled to the first source/drain of the sixth pixel transistor by a nineth conductive interconnect on the first semiconductor chip; and
a sixth bonding pad on the third semiconductor chip and coupled to the second source/drain of the transfer transistor by a tenth conductive interconnect on the third semiconductor chip, wherein the sixth bonding pad is bonded and coupled to the fifth bonding pad.

14. The integrated chip of claim 7, wherein the second conductive interconnect is a top conductive line on the first semiconductor chip, the integrated chip further comprising:
a first bonding contact on the first semiconductor chip and extending from the first bonding pad to the top conductive line; and
a top conductive via on the first semiconductor chip and extending from the second conductive interconnect to the second electrode of the first LOFIC.

15. A method for forming an integrated chip, the method comprising:
forming a photodetector and transfer transistor, the transfer transistor including a first source/drain, a second source/drain, and a gate, wherein the first source/drain of the transfer transistor is coupled to the photodetector;
forming a first pixel transistor along a first semiconductor substrate of a first semiconductor chip, the first pixel transistor including a first source/drain, a second source/drain, and a gate, wherein the first source/drain of the first pixel transistor is coupled to the second source/drain of the transfer transistor;
forming a first conductive interconnect on the first semiconductor chip and coupled to the second source/drain of the first pixel transistor;
forming a first capacitor on the first semiconductor chip, the first capacitor including a first electrode, a second electrode, and a dielectric between the first electrode and the second electrode, wherein the first electrode is coupled to the first conductive interconnect;
forming a second conductive interconnect on the first semiconductor chip and coupled to the second electrode of the first capacitor;
forming a first bonding pad on the first semiconductor chip and coupled to the second conductive interconnect;
forming a second pixel transistor along a second semiconductor substrate of a second semiconductor chip, the second pixel transistor including a first source/drain, a second source/drain, and a gate;
forming a third conductive interconnect on the second semiconductor chip and coupled to the first source/drain of the second pixel transistor;
forming a second bonding pad on the second semiconductor chip and coupled to the third conductive interconnect; and
bonding the first bonding pad to the second bonding pad, wherein the second electrode of the first capacitor is coupled to the first source/drain of the second pixel transistor by the second conductive interconnect, the first bonding pad, the second bonding pad, and the third conductive interconnect.

16. The method of claim 15, further comprising:
forming a third pixel transistor along the first semiconductor substrate of the first semiconductor chip, the third pixel transistor including a first source/drain, a second source/drain, and a gate, wherein the first source/drain of the third pixel transistor is coupled to the second source/drain of the first pixel transistor and the first electrode of the first capacitor, and wherein the second source/drain the of the third pixel transistor is coupled to a supply voltage terminal;
forming a fourth pixel transistor along the first semiconductor substrate of the first semiconductor chip, the fourth pixel transistor including a first source/drain, a second source/drain, and a gate, wherein the first source/drain of the fourth pixel transistor is coupled to the second source/drain of the third pixel transistor and the supply voltage terminal, and wherein the gate of the fourth pixel transistor is coupled to the second source/drain of the transfer transistor;
forming a fifth pixel transistor along the first semiconductor substrate of the first semiconductor chip, the fifth pixel transistor including a first source/drain, a second source/drain, and a gate, wherein the first source/drain of the fifth pixel transistor is coupled to the second source/drain of the fourth pixel transistor; and
forming an application specific integrated circuit coupled to the second source/drain of the fifth pixel transistor.

17. The method of claim 16, wherein the photodetector and the transfer transistor are formed along the first semiconductor substrate of the first semiconductor chip, and wherein the application specific integrated circuit is formed on the second semiconductor chip.

18. The method of claim 16, wherein the photodetector and the transfer transistor are formed along the second semiconductor substrate of the second semiconductor chip, and wherein the application specific integrated circuit is formed on a third semiconductor chip.

19. The method of claim 16, wherein the photodetector and the transfer transistor are formed along a third semiconductor substrate of a third semiconductor chip, and wherein the application specific integrated circuit is formed on the second semiconductor chip.

20. The method of claim 15, further comprising:
forming a third pixel transistor along the first semiconductor substrate of the first semiconductor chip, the third pixel transistor including a first source/drain, a second source/drain, and a gate, wherein the first source/drain of the third pixel transistor is coupled to the second source/drain of the transfer transistor, and wherein the second source/drain of the third pixel transistor is coupled to the first source/drain of the first pixel transistor;
forming a fourth conductive interconnect on the first semiconductor chip and coupled to the second source/drain of the third pixel transistor and the first source/drain of the first pixel transistor; and
forming a second capacitor on the first semiconductor chip, the second capacitor including a first electrode, a second electrode, and a dielectric between the first electrode and the second electrode, wherein the first electrode of the first capacitor is coupled to the fourth conductive interconnect.
